(19) United States
(12) Patent Application Publication
(10) Pub. No.: US 2025/0008690 A1
(43) Pub. Date: Jan. 2, 2025

(54) Coolant Flow Enhancement

(71) Applicant: Green Revolution Cooling, Inc., Austin, TX (US)

(72) Inventor: John H. BEAN, JR., Littlestown, PA (US)

(21) Appl. No.: 18/756,714

(22) Filed: Jun. 27, 2024

Related U.S. Application Data
(60) Provisional application No. 63/524,186, filed on Jun. 29, 2023.
(60) Provisional application No. 63/598,383, filed on Nov. 13, 2023.

(51) Int. Cl. H05K 7/20

(52) U.S. Cl. CPC H05K 7/20272; H05K 7/20236; H05K 7/20263; H05K 7/20318; H05K 7/20781

(57) ABSTRACT

An immersion cooling system including an immersion coolant tank, a heat exchanger, and an eductor. The immersion coolant tank contains the heat generating electronic equipment. The heat exchanger removes heat absorbed by a first portion of a volume of dielectric cooling fluid within the immersion coolant tank. The eductor receives the first portion of the volume of dielectric cooling fluid through a first port from the heat exchanger as motive fluid and receives a second portion of the volume of dielectric cooling fluid from the immersion coolant tank through a second port as a suction fluid. The motive fluid may create suction by passing through the eductor, which suction draws the suction fluid into the eductor. The eductor may also mix the motive fluid with the suction fluid inside the eductor; and releasing the mixture of the motive fluid and the suction fluid through a third port.

### RELATED APPLICATIONS

This application claims the benefit of priority from U.S. provisional application Ser. No. 63/524,186 entitled “Coolant Flow Enhancement” filed on Jun. 29, 2023, and U.S. provisional application Ser. No. 63/598,383 entitled “System and Method for Flow Rate Enhancement, Immersion Cooling System for Servers with Targeted Flow to High Heat Flux Items” filed on Nov. 13, 2023, the entire contents of both of which are incorporated herein by reference for all purposes.

### BACKGROUND

Data centers may be used by organizations to assemble, process, store, and disseminate large amounts of data. Many enterprises rely heavily on the applications, services and data contained within a data center, making it a critical asset for everyday operations.

A data center facility may include, for example, systems for storing, sharing, accessing, and processing data, physical infrastructure for supporting data processing and data communications, and utilities such as cooling, electricity, and network security access. Data centers may face challenges that may include, for example, cooling ever-increasing heat loads; the cost of power, sustainability, and the ability to scale quickly and easily. As the usage of high-density technology continues to increase, the amount of heat that is generated continues to increase. The increased heat results in pushing the computing hardware to its limit. This trend is expected to continue.

Immersion cooling racks provide a bath of dielectric fluid in a tank, which is often used to cool computer servers or other electronic equipment in data centers. Computer servers or other electronic equipment may be mounted on immersion cooling racks within the tank. The dielectric fluid may be circulated around computer servers or other electronic equipment such that heat can be rejected from one or more computer servers or other electronic equipment mounted within the tank. While the flow of the dielectric fluid in and around the heat-generating electronic equipment immersed in the tank helps remove heat from the electronic equipment generally, providing adequate localized cooling to some of the most intensive heat-generating elements of the electronic equipment, such as CPUs and GPUs, remains challenging. The surfaces of those intensive heat-generating elements tend to have dense (i.e., small pitch) fin patterns that make achieving heat transfer velocity targets difficult. Additionally, pressure losses of side stream flow channels may be lower than pressure losses of specific heat transfer surfaces, thereby allowing adverse amounts of bypass flow of dielectric cooling fluids.

While the benefits of immersion cooling of electronics are well understood, such as for cooling servers and other information technology equipment (ITE), there remains a need to further enhance this technology for high heat flux components. In particular, increases in total dissipated power (TDP) per socket for central processing units (CPUs) and graphics processing units (GPUs) have challenged the effectiveness and efficiency of conventional cooling systems.

### SUMMARY OF INVENTION

Various aspects include systems, devices, and methods for immersion cooling of heat generating electronic equipment. An immersion cooling system may include an immersion coolant tank, a heat exchanger, and an eductor. The immersion coolant tank may be configured to contain the heat generating electronic equipment. The heat exchanger may be configured to remove heat absorbed by a first portion of a volume of dielectric cooling fluid within the immersion coolant tank. The eductor may be configured to receive the first portion of the volume of dielectric cooling fluid through a first port from the heat exchanger as motive fluid and receive a second portion of the volume of dielectric cooling fluid from the immersion coolant tank through a second port as a suction fluid. The motive fluid may create suction by passing through the eductor, which suction draws the suction fluid into the eductor. The eductor may also mix the motive fluid with the suction fluid inside the eductor; and releasing the mixture of the motive fluid and the suction fluid through a third port.

In various aspects, the eductor may be configured to direct the mixture of the motive fluid and the suction fluid released through the third port toward at least a portion of the heat generating electronic equipment. The eductor may be a liquid venturi eductor. The second portion of the volume of dielectric cooling fluid may be drawn from an area within the immersion coolant tank that may be immediately adjacent at least one heat generating component of the heat generating electronic equipment. The second portion of the volume of dielectric cooling fluid may be drawn from an area within the immersion coolant tank that may be remote from a mixing chamber of the eductor in which the motive fluid may be mixed with the suction fluid.

Various aspects may further include a heatsink shroud at least partially enclosing at least one heat generating component of the heat generating electronic equipment, wherein the second portion of the volume of dielectric cooling fluid may be drawn from within the heatsink shroud. The eductor may be primarily disposed within the immersion coolant tank.

Various aspects may further include a heat removal system coupled to the heat exchanger and configured to cool a secondary coolant used by the heat exchanger to cool the first portion of the volume of dielectric cooling fluid.

Various aspects may further include a second heat exchanger configured to remove heat absorbed by the second portion of the volume of dielectric cooling fluid from the immersion coolant tank before being received in the eductor as the suction fluid. The second heat exchanger may be a chiller.

Various aspects may further include a condensing unit coupled to the second heat exchanger. The heat exchanger configured to remove heat absorbed by the first portion of the volume of dielectric cooling fluid within the immersion coolant tank may be a chiller.

Various aspects may further include a condensing unit coupled to the heat exchanger configured to remove heat absorbed by the first portion of the volume of dielectric cooling fluid. The heat exchanger may be located outside the immersion coolant tank.

Various aspects may include an immersion cooling system for heat generating electronic equipment, including an immersion coolant tank defining an open interior volume configured to hold the heat generating electronic equipment at least partially submerged in dielectric cooling fluid; a heat exchanger configured to receive a first portion of the dielectric cooling fluid released from the immersion coolant tank, wherein the heat exchanger may be configured to cool and return the first portion of the dielectric cooling fluid to the immersion coolant tank; coolant circulation lines, wherein the coolant circulation lines include: a coolant return line fluidly coupling an outlet port of the immersion coolant tank to the heat exchanger; a coolant supply line fluidly coupling the heat exchanger to an inlet port of the immersion coolant tank; a coolant bypass line coupling the coolant return line to the coolant supply line, wherein the coolant bypass line may be configured to enable a second portion of the dielectric cooling fluid released from the immersion coolant tank to bypass the heat exchanger before being delivered to the inlet port; a first pump configured to move the dielectric cooling fluid between the outlet port and the inlet port via the coolant circulation lines; and at least one bypass flow control device configured to control coolant flow to bypass the heat exchanger.

In various aspects, the at least one bypass flow control device includes a valve disposed downstream of the first pump in at least one of the coolant circulation lines. The at least one bypass flow control device includes a second pump configured to move the dielectric cooling fluid between the heat exchanger and the inlet port. The outlet port provides a dielectric cooling fluid exit from a return manifold configured to release warmer dielectric cooling fluid from the immersion coolant tank. The inlet port provides a dielectric cooling fluid entrance to a supply manifold configured to receive and distribute colder dielectric cooling fluid into the immersion coolant tank.

In various aspects, the immersion cooling system may further include a directed coolant supply line configured to deliver at least a portion of the colder dielectric cooling fluid from the supply manifold to an area within the immersion coolant tank that may be immediately adjacent to at least one heat generating component of the heat generating electronic equipment.

Various aspects may further include a flow control device configured to control the flow of the portion of the colder dielectric cooling fluid from the supply manifold to the area within the immersion coolant tank immediately adjacent to the at least one heat generating component.

Various aspects may further include a heatsink shroud at least partially enclosing the at least one heat generating component of the heat generating electronic equipment, wherein the portion of the colder dielectric cooling fluid delivered immediately adjacent to the at least one heat generating component may be delivered within the heatsink shroud.

In various aspects, the inlet port further includes a direct flow supply manifold configured to receive a first portion of a colder dielectric cooling fluid received from the coolant supply line and distribute the first portion of the colder dielectric cooling fluid to a first area within the immersion coolant tank that may be immediately adjacent to at least one heat generating component of the heat generating electronic equipment; and a tank bulk supply manifold configured to receive a second portion of colder dielectric cooling fluid received from the coolant supply line and distribute the second portion of the colder dielectric cooling fluid to a second area within the immersion coolant tank that may be remote from the first area.

In various aspects, the coolant supply line includes a diverting valve for directing the first portion of the colder dielectric cooling fluid to the direct flow supply manifold and for directing the second portion of the colder dielectric cooling fluid to the tank bulk supply manifold. The diverting valve may be an adjustable valve. The coolant supply line includes a second pump configured to control a flow ratio of the first portion of the colder dielectric cooling fluid that flows to the direct flow supply manifold and the second portion of the colder dielectric cooling fluid that flows to the tank bulk supply manifold. The coolant supply line branches into a direct flow supply line and tank bulk flow supply line, wherein the direct flow supply line may be configured to deliver the first portion of the colder dielectric cooling fluid to the direct flow supply manifold and the tank bulk flow supply line may be configured to deliver the second portion of the colder dielectric cooling fluid to the tank bulk supply manifold, wherein the second pump may be disposed along the direct flow supply line. The coolant supply line includes a bypass branch line connecting the direct flow supply line and the tank bulk flow supply line, wherein the second pump may be bypassed by the bypass branch line. The bypass branch line includes a valve for controlling a flow between the direct flow supply line and the tank bulk flow supply line. The bypass branch line includes a one-way check valve preventing a flow from the direct flow supply line to the tank bulk flow supply line.

### BRIEF DESCRIPTION OF THE DRAWINGS

FIG. 1 a perspective view of an immersion cooling system in accordance with various embodiments.

FIG. 2 is a schematic drawing of an immersion cooling system that includes coolant flow enhancement elements according to various embodiments.

FIG. 3 is a schematic drawing of an immersion cooling system that includes coolant flow enhancement elements according to various embodiments.

FIG. 4 is a schematic drawing of an immersion cooling system that includes coolant flow enhancement elements according to various embodiments.

FIGS. 5A-5B are schematic drawings of liquid venturi eductors that may be used as a coolant flow enhancement element according to various embodiments.

FIG. 6 is a schematic drawing of a nozzle/diffuser eductors that may be used as a coolant flow enhancement element according to various embodiments.

FIG. 7 is a schematic drawing of an immersion cooling system that includes a flow restriction device according to various embodiments.

FIGS. 8A-8B are schematic drawings of an immersion cooling system that includes a pump as a flow restriction device according to various embodiments.

FIG. 9 is a schematic drawing of an immersion cooling system that supplies a direct flow supply manifold and a separate tank bulk supply manifold according to various embodiments.

FIG. 10 is a schematic drawing of an immersion cooling system similar to that in FIG. 9, additionally including an additional pump controlling flow ratios according to various embodiments.

FIG. 11 is a schematic drawing of another immersion cooling system that supplies a direct flow supply manifold and a separate tank bulk supply manifold according to various embodiments.

### DETAILED DESCRIPTION

Various embodiments will be described in detail with reference to the accompanying drawings. Wherever possible, the same reference numbers will be used throughout the drawings to refer to the same or like parts. References made to particular examples and implementations are for illustrative purposes and are not intended to limit the scope of the claims.

Data centers typically have a significant carbon footprint. As the need for these data centers continues to surge, an increase in power usage and greenhouse gas emissions is expected to surge with the demand for data centers. Greenhouse gas emissions may contribute to extreme weather and put the health of our planet at risk. There is growing demand from both the public and industry to reduce the environmental impact of all businesses. Thus, sustainability has moved into the corporate domain and, due to regulations and the cost implications of reducing a carbon footprint, mitigation of greenhouse gas emissions and generated heat may be critical. With these economic and political pressures driving data centers to seek alternative approaches to conventional facility design, owners and operators are turning to liquid immersion cooling to reduce power use and drive sustainability efforts.

The computational power of the servers continues to be pushed, requiring greater heat dissipation capability. With these pressures driving data centers to seek alternative approaches to conventional facility design. Immersion cooling is a popular and proven solution for heat dissipation to reduce power use and drive sustainability efforts. Specifically, the dielectric fluid, in which computing devices such as servers may be immersed, is a far more efficient thermal dissipator than air. In addition, immersion cooling does not require fans which means more power may be directed to the operation of the computing device (i.e., server).

While the benefits of immersion cooling of electronics servers and other Information Technology Equipment (ITE) are well understood from a thermodynamic perspective and reliability there remains need to further enhance this technology for high heat flux components in response to increasing TDP (Total Dissipated Power) per socket for CPUs and GPUs. It is desirable to increase the fluid flow rate to servers that incorporate provisions to target enhanced flow to specific high heat flux items like CPU(s) and GPU(s). It is understood that by increasing the flow rate, the thermal resistance can be significantly reduced. The net effect being significantly more heat can be passed from the case (lid) of the CPUs or GPUs to the dielectric cooling fluid for the same temperature difference between the CPU/GPU case(s) and fluid. In some instances, the thermal resistance can be better than cut in half thereby doubling the heat transfer for a given temperature difference. One challenge is to enhance fluid flow while avoiding the addition of active components e.g., extra pumps or burdening balance of immersion cooling system with abnormally high flow rates which would result in higher system losses thereby demanding more power. The various embodiments disclosed herein incorporate the use of high flow rate pumps and internal circulation system to support high flow to servers while provisioning for dielectric cooling via a side stream heat exchanger that does not burden the total pumping power of system by pushing unnecessary flow through the heat exchanger (dielectric to water).

Immersion cooling racks, in accordance with various embodiments provide a volume of dielectric cooling fluid in a tank. The dielectric cooling fluid may be circulated in the tank to absorb heat from heat generating components, which absorbed heat may be subsequently rejected from the heated dielectric cooling fluid via a cooling device, such as an evaporative cooling tower, and then the cooled dielectric cooling fluid may be returned/delivered to the heat-generating electronic components that would otherwise overheat. A liquid-to-liquid heat exchanger may be used between a dielectric loop of a tank and a water loop of an evaporative cooling tower. Other means of heat rejection to an ambient atmosphere may also include dry-coolers and adiabatic assisted dry-coolers, as well as chillers both air and water cooled.

Various embodiments enhance flow rates to specific elements of electronic equipment and include techniques and specific geometries that will help facilitate significant power handling increases in components within immersion cooling tanks. Localized enhanced flow rate(s) in a server may individually or in aggregate be less than, equal to, or greater than bulk flow rate through the server. In some cases, localized enhanced flow rates may improve performance at greater volumetric rates than the bulk flow through the server; i.e., where the specific heat capacity of server bulk flow is sufficient to address appropriate net temperature changes, but other properties of the fluid (e.g., higher viscosity) may need the flow to be enhanced to improve local heat transfer coefficients.

Certain locations on electronic equipment, such as a server, namely the central processing unit (CPU) or the graphics processing unit (GPU), require additional cooling compared to the rest of the architecture. This may be due to the CPU or GPU being the most intensive heat generating element. However, sizing the entire fluid circulation system around providing adequate flow across the CPU and/or GPU for cooling purposes is generally impractical. Thus, various embodiments include a dedicated dielectric fluid pump and coolant shroud to promote additional flow over the CPU, GPU, and heatsink. The coolant shroud may be a shaped plastic containment system that separates fluid flow near the CPU and heatsink from the bulk fluid.

Various embodiments disclosed herein include coolant flow enhancement elements that may increase the fluid flow rate through the heatsinks mounted on the CPUs and/or GPUs in immersion cooling systems.

One challenge is to enhance fluid flow while avoiding the addition of active components, such as extra pumps. Various embodiments described herein use an eductor to create a siphon effect at the outlet of one or more shrouds that cover heatsink(s). The system may be simplified by using a single pump, already present, in combination with the eductor. In some embodiments, the eductor may be a liquid venturi eductor.

Immersion cooling racks, in accordance with various embodiments, provide a pool of dielectric cooling fluid in a tank. The dielectric cooling fluid may be circulated in the tank such that heat may be rejected from the heated dielectric cooling fluid to the atmosphere (typically via an external cooling device such as an evaporative cooling tower) and cooled dielectric cooling fluid may then be delivered to the heat-generating electronic components that would otherwise overheat.

Various embodiments disclosed herein provide for systems and methods for enhancing flow distribution of the cooled dielectric cooling fluid through the immersion tank configured to house multiple computing devices.

Various embodiments disclosed herein provide for systems and methods for ensuring a distribution of the cooled dielectric cooling fluid through the immersion tank configured to house multiple computing devices. Components of the cooling system may be scalable to different form factors and input variables.

Dielectric immersion cooling systems for use in various embodiments may include at least one rack, independently operable computing devices (e.g., servers) configured to be inserted into the rack vertically, and primary flow of dielectric cooling fluid through the rack, with heat removal through a secondary flow of water or other cooling fluid loop. The dielectric immersion cooling system may provide heat transfer from a primary flow of the dielectric cooling fluid to a secondary flow of a secondary coolant (e.g., water), such as in a heat exchanger (e.g., a brazed plate heat exchanger). Additionally, the secondary flow may be of a refrigerant with the heat transfer occurring in an evaporator of a vapor compression Rankine Cycle.

The terms “dielectric cooling fluid” and “oil” may be used interchangeably herein to refer to any single-phase dielectric coolant, including but not limited to, a mineral oil, liquid hydrocarbon (e.g., Polyalphaolefin), or a synthetic derived liquid hydrocarbon (e.g., Gas-to-Liquids).

The term “water” as used herein refers to water or a water mix, such as water and glycol mix commonly used in combination with a chiller or dry cooler, or water and chemical mix, such as commonly used in direct cooling of water by a cooling tower. As will be understood by one of ordinary skill in the art, water is merely an example of one secondary circuit cooling fluid according to various embodiments and is not intended to be limiting.

The term “eductor” as used herein refers to a device that uses fluid dynamics with a motive fluid creating a suction force that draws in another fluid for mixing or pumping purposes. For example, a jet pump or venturi pump, such as a liquid venturi eductor that uses fluid flow to draw-in (i.e., move) a suction fluid. The eductor includes a first port configured to receive the motive fluid, a second port configured to receive a suction fluid, a mixing section configured to combine the motive fluid and the suction fluid, and a third port configured to expel the mixture of the motive fluid and the suction fluid. This three-port structure may take the form of a T-coupling, Y-coupling, r-coupling, or other similar structures that unite and distribute fluid flows. Also, the three-ports may each be similarly sized, shaped, or configured, or one or more of the ports may differ in any of those regards. The structure of the eductor may ensure efficient energy transfer and fluid movement, utilizing the Venturi effect for operation.

The immersion coolant tank, in accordance with various embodiments, is configured to efficiently cool heat-generating electronic equipment by utilizing a unique combination of components and fluid dynamics principles. In some embodiments, the tank includes an eductor that draws in dielectric cooling liquid as suction fluid from various areas within or outside the tank, such as generally from the tank and/or through shroud coolant removal lines connected directly to heatsink shrouds surrounding specific components such as CPUs and GPUs. The motive fluid flowing into the mixing chamber of each eductor may create a low-pressure area, which pulls in more dielectric cooling liquid as suction fluid at twice its initial rate for enhanced heat transfer around these useful areas.

In some embodiments, the eductor may include a nozzle as part of the first port and/or a diffuser for the third port. The nozzle works by converting the pressure energy of the motive fluid into velocity energy, which can then be used to generate the suction force that draws-in the suction fluid or enhances the suction force otherwise generated by the motive fluid alone (i.e., without the pressure-to-velocity energy conversion). In this way, the nozzle may be configured to receive the motive fluid and convert pressure energy therein into velocity energy, creating a high-velocity jet. The jet of motive fluid is then directed into a mixing section, along with the suction fluid drawn-in to the eductor. Within the mixing section, the suction fluid is entrained and mixed with the motive fluid. The mixed fluids may then exit the eductor through the diffuser, where the velocity energy may be partially converted back into pressure energy.

Various aspects include devices, systems, and methods for providing fluid distribution of a dielectric fluid to a plurality of computing devices. Some aspects may include a tank defining an open interior volume. The tank may include a first wall with a first end and a second wall with a second end, in which the first end and the second end are spaced away from each other. A supply manifold, with a plurality of outlets, can be located on the first wall, and a return manifold can be located on the second wall. The dielectric fluid may be located inside of the open interior volume of the tank and a fluid level line of the dielectric fluid can be perpendicular to the first wall and the second wall. The plurality of computing devices can be located inside of the open interior volume and the plurality of computing devices can be immersed inside of the dielectric fluid. A main supply line may be located outside of the tank, the main supply line can be connected to an inlet of the supply manifold, and the main return line may be connected to an outlet of the return manifold. A flow device can be located on the tubing and is adjacent to both the supply manifold and the first wall. The dielectric fluid can be heated by the plurality of computing devices and exit the tank via the return manifold. The elements of the circulation system connected to the return and supply manifold may include: a pump, a heat exchanger, a device to create pressure differential across the heat exchanger in fluid connection with the pump outlet or the device to create pressure differential may be replace with a second pump to create the pressure differential needed for flow through the heat exchanger.

Various aspects include devices, systems, and methods for increasing the fluid flow rate through the heatsinks mounted on the CPUs and/or GPUs in immersion cooling systems. By increasing the flow rate, the thermal resistance of the cooled devices may be significantly reduced. The net effect being significantly more heat can be passed from the case or lid of the CPUs or GPUs to the dielectric cooling fluid for the same temperature difference between the CPU/GPU case(s) and fluid. The case or lid refers to the metal package that protects the die (i.e., the silicon with all of the circuits). The case may contain or enclose an internal heat spreader (IHS) and thermal interface material (TIM). The lid more specifically may refer to a top of the case, which may correspond to the surface from which the heatsink conducts heat (e.g., through another TIM). In some instances, the thermal resistance may be decreased by half or better, thereby doubling the heat transfer for a given temperature difference.

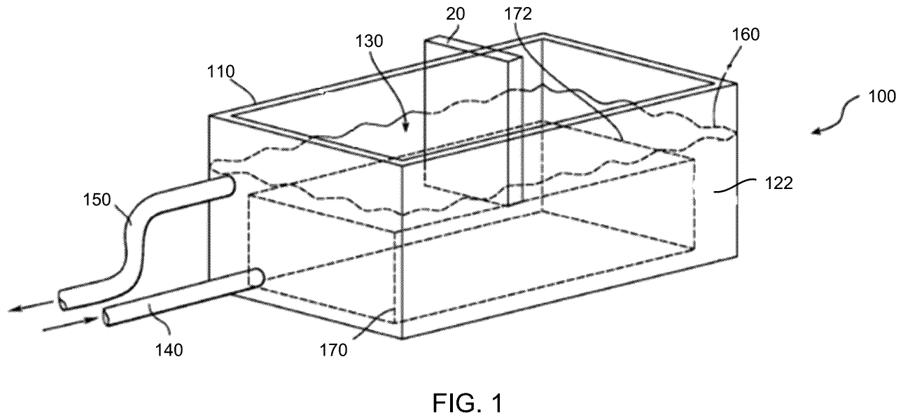

FIG. 1 illustrates various aspects of an immersion coolant system 100 for immersing a rack of electronic equipment, such as independently operable servers, in a dielectric cooling fluid 122. The immersion coolant system 100 may include an immersion coolant tank 110 and mounting members for mounting computer servers or other electronic equipment, as will be described in more detail hereinafter. The immersion coolant tank 110 may be fabricated of steel, a sufficiently strong plastic that is compatible with the dielectric liquid coolant used as a cooling medium, or other suitable material. The immersion coolant tank 110 may face upward with an open top 130 to form an open interior volume and may be shaped to have a length (L), width (W), and height (H) with the minimum footprint to insert multiple pieces of electronic equipment 20 (e.g., servers). Suitable mounting members may be used to mount the electronic equipment 20 in the immersion coolant tank 110 to form the server rack 170 therein. The immersion coolant tank 110 may be shaped, dimensioned, and sized such that multiple standard-sized pieces of electronic equipment 20 (e.g., servers) can be supported without significant modification.

The immersion coolant tank 110 may be fabricated to have an inlet pipe or line 140 from a piping system connected to a heat exchanger for the flow of lower temperature or cooled liquid coolant into the immersion coolant tank 110 and an outlet pipe or line 150 connected to collection piping for the flowing or pumping of heated coolant out of the immersion coolant tank 110 to an external heat exchanger associated with one or more heat-rejection or cooling systems.

The server rack 170 may have a number of different implementations. Preferably, the mounting members are configured to receive the multiple pieces of electronic equipment 20 (e.g., servers) in a vertical orientation, thereby minimizing the footprint of the multiple pieces of electronic equipment 20 (e.g., servers) relative to the ground, and with the “front” panel facing upward for easy installation and removal of a server without the need to remove or disturb any other server within the immersion coolant tank 110.

The mounting members may be also configured to mount each of the multiple pieces of electronic equipment 20 (e.g., servers) such that the top level 160 of the dielectric coolant completely submerges the top level 172 of the server rack 170 formed by the multiple pieces of electronic equipment 20 (e.g., servers). As a consequence, a volume of liquid coolant collects in a common area above the server rack 170 to improve the circulation of the liquid coolant through the multiple pieces of electronic equipment 20 (e.g., servers), thereby enhancing the cooling of each respective piece of electronic equipment 20. The mounting members may also be configured to mount the multiple pieces of electronic equipment 20 (e.g., servers) in the server rack 170 above the bottom of the immersion coolant tank 110 to create a volume of liquid coolant between each respective server and the bottom of the immersion coolant tank 110 such that the flow of the dielectric liquid coolant through the servers is improved.

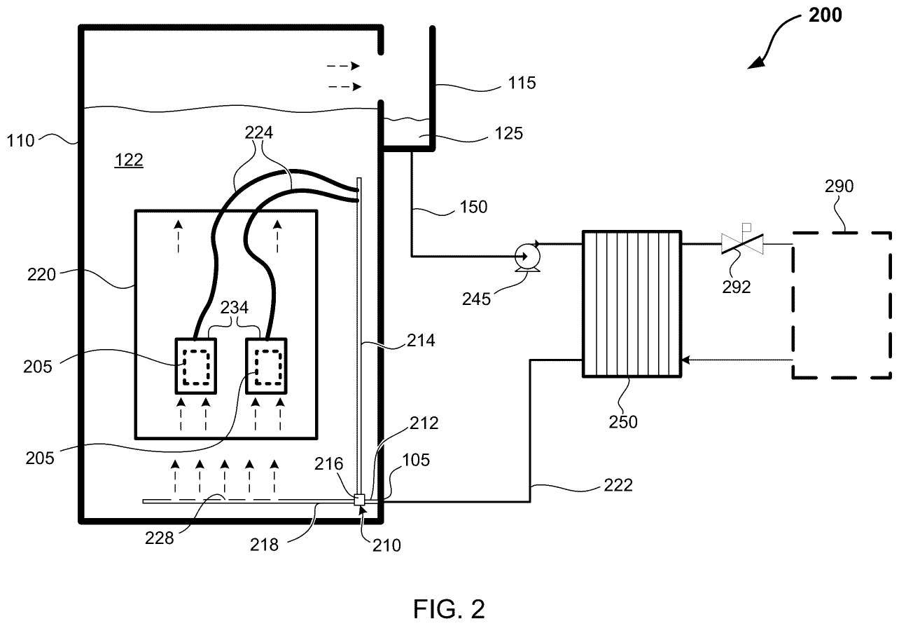

FIG. 2 is a schematic drawing of an immersion cooling system 200 that includes coolant flow enhancement elements according to various embodiments. With reference to FIGS. 1-2, an immersion coolant tank 110 may contain heat generating electronic equipment 220, such as a plurality of rack-mounted computing devices (e.g., electronic equipment 220, like servers) mounted on a server rack (e.g., 170). The heat generating electronic equipment 220 may be submerged within a primary circuit dielectric cooling fluid 122, such as oil. Heat generating components 205 of each piece of heat generating electronic equipment 220 may generate heat, such as a central processing unit (CPU), graphics processing unit (GPU), memory modules (RAM), power supply unit (PSU), storage device, network interface card (NIC), and/or other expansion cards. The heat from the plurality of heat generating electronic equipment 220 may be dissipated using the primary circuit dielectric cooling fluid 122. The immersion coolant tank 110 may include a main well that holds the server rack submerged within the primary circuit dielectric cooling fluid 122, as well as a return reservoir 115 that is coupled to the tank 110. The return reservoir 115 is configured to capture return dielectric cooling fluid 125 when a surface level of the primary circuit dielectric cooling fluid 122 in the main well of the tank 110 rises above a return level. The return dielectric cooling fluid 125 will tend to be some of the hotter dielectric cooling fluid in the tank 110. The return dielectric cooling fluid 125 is part of the primary circuit dielectric cooling fluid 122, captured within the return reservoir 115.

A pump 245 may draw the heated primary circuit dielectric cooling fluid 122 from the server rack, and/or the tank 110, and direct it to a heat exchanger 250 (e.g., a dielectric cooling fluid-to-water heat exchanger). In particular, the pump 245 may draw return dielectric cooling fluid 125 from the return reservoir 115 via a primary circuit coolant removal line 150, which may remove the return dielectric cooling fluid 125 that was heated by the heat generating electronic equipment 220. Alternatively, the pump 245 may draw the primary circuit dielectric cooling fluid 122 directly from the main well of the tank 110. The heat exchanger 250 may expel a heated secondary cooling fluid and be resupplied with fresh cooler new secondary cooling fluid, such as by using a fluid cooler with or without adiabatic cooling assist, a cooling tower, or chiller (water or air-cooled). The heat exchanger 250 may optionally redirect a heated secondary cooling fluid (e.g., water or a water/glycol mixture) to a heat removal system 290 and allow the cooled primary circuit dielectric cooling fluid 122 to return to the server rack and/or the tank 110. The rate of flow (or lack thereof) of the heated secondary cooling fluid to the heat removal system 290 may be controlled by a valve 292 or other flow control element. The heat removal system may cause the captured heat to be expelled or reused, after which the cooled secondary cooling fluid may be returned to the heat exchanger 250.

The tank 110 may optionally have a hinged or removable lid (not shown), or an open top. The tank 110 may be fabricated of steel, a sufficiently strong plastic that is compatible with the dielectric cooling fluid 122 used as a cooling medium, or other suitable material. The tank 110 may contain a plurality of independently operable data processing modules (e.g., heat generating electronic equipment 220) mounted vertically. Each data processing module may be independently removable and replaceable without affecting the position or operation of other data processing modules. In this way, a neighboring data processing module need not be powered down or made to run idle while another data processing module within the tank is removed and/or replaced. The independently operable data processing modules may be mounted in an array that is arranged horizontally on/in the server rack and immersed at least partially in the primary circuit dielectric cooling fluid 122.

In various embodiments, the primary circuit dielectric cooling fluid 122 may be used as a motive fluid that is pumped through the heat exchanger 250 by means of a pump 245 (e.g., a centrifugal dielectric circulation pump) and returned to the tank 110 via a distribution manifold and/or inlet port 105 (e.g., disposed at the bottom of the tank 110). The inlet port 105 may be configured to direct the returned dielectric cooling fluid 122 toward and/or through at least one rack unit (RU) to facilitate cooling of one or more particular piece of heat generating electronic equipment 220. In some cases, each RU may be aligned or near an inlet port 105 so as to more directly received at least a portion of the returned dielectric cooling fluid 122 that has been cooled by the heat exchanger 250.

The heat exchanger 250 may be a useful component in this immersion cooling system that facilitates efficiently transferring thermal energy from dielectric fluid to secondary coolant medium for further dissipation. In various embodiments of this invention, multiple types of heat exchangers may be employed depending on specific requirements: brazed plate heat exchanger (BPE), spiral wound tube-and-shell type, shell-and-tube design with a helical coil configuration for enhanced turbulence promotion, or even compact counter-flow and cross-counter flow designs. Each embodiment offers distinct advantages in terms of thermal performance, pressure drop management, and overall system efficiency.

In one exemplary implementation, the heat exchanger 250 is designed as a liquid-to-air heat exchanger, such as a fin tubular heat exchanger. This design enables precise control overflow rates, pressure drops, and thermal resistance while minimizing the overall footprint required for installation.

Another embodiment envisions a spiral wound tube-and-shell type heat exchanger with multiple turns of increasing diameter to increase surface area exposure between dielectric fluid flowing through inner tubes and secondary coolant medium circulating within outer shells. This design allows for enhanced convective transfer by creating swirling motion, which may be further optimized using turbulence promoters or vortex generators.

In yet another embodiment, the shell-and-tube heat exchanger may be designed with a helical coil configuration to promote turbulent flow patterns between dielectric fluid flowing through inner tubes and secondary coolant medium circulating within outer shells. This design enables efficient thermal transfer while minimizing pressure drops by leveraging natural convection forces in conjunction with controlled pumping systems.

In addition, compact counter-flow or cross-counter flow heat exchangers may be employed for applications where space constraints are a concern. These designs utilize opposing flows of dielectric fluid and secondary coolant medium to create intense convective mixing within the exchange surfaces, resulting in enhanced thermal transfer rates while minimizing overall system size.

Furthermore, various embodiments may incorporate additional features such as: (a) internal fins or turbulators on heat exchanger tubes for increased surface area exposure; (b) spiral-shaped flow channels with varying cross-sectional areas to optimize fluid dynamics and convective mixing within the exchange surfaces; (c) integrated pumps or fans for enhanced circulation of secondary coolant medium, especially in compact designs where space is limited.

In accordance with various embodiments, some or all such inlet ports 105 may be equipped with one or more eductors 210 (e.g., liquid venturi eductor). Each eductor 210 may include a first port 212, a second port 214, a mixing section 216, and a third port 218. The cooled supply dielectric cooling fluid 122 received through the inlet port 105 may be directed into the first port of the eductor 210 and act as a relatively high velocity motive fluid that creates a low pressure at the second port, which is configured to pull-in a suction fluid into the mixing section 216 of the eductor 210. The mixture of motive fluid and suction fluid is then ejected through the third port 218. Each of the first port 212, the second port 214, and the third port 218 may include a proximal end disposed closer to the mixing section 216 and a distal end disposed further from the mixing section.

In accordance with various embodiments, one or more of the ports of the eductor(s) 210 (e.g., first port 212, second port 214, and/or third port 218) may include extension elements that extend away from the mixing section 216. These elements are configured to receive or expel dielectric fluid from or to an area remote from the eductor 210. For example, the distal end of the first port 212 may be disposed inside the tank 110, outside the tank 110, or in a fitting that provides an inlet port 105 into the tank 110. The distal end of the first port 212 may be coupled to a first port extension 222 that reaches the heat exchanger 250. Alternatively, the first port extension 222 may be integrally formed with one or more elements of the first port 212.

The first port 212 receives motive fluid from the primary circuit, which creates suction by passing through its internal mixing chamber section. This low-pressure area draws in dielectric cooling liquid as suction fluid via one of several possible paths: directly adjacent heat generating components (e.g., CPUs), shroud coolant removal lines connected to heatsink shrouds surrounding specific components, or even from areas farther away within the immersion tank.

The second port 214 serves as a suction intake, which may be coupled to one or more shroud coolant removal lines 224 that are configured to draw suction fluid from an area inside the tank 110 that is remote from the eductor 210, with the drawn suction fluid pulled into the internal mixing chamber section. For example, one or more shroud coolant removal lines 224 may draw fluid from an area immediately adjacent a particular heat generating component 205. As used herein, the expression “immediately adjacent” refers to an area that is directly next to or in very close proximity to another area or object, without any significant space or barrier in between.

In the context of the second portion of the volume of dielectric cooling fluid that is drawn from an area within the immersion coolant tank that is immediately adjacent at least one heat generating component of the heat generating electronic equipment, the expression “immediately adjacent” describes an area within the immersion coolant tank that is very close to, or directly next to, at least one heat generating component of the heat generating electronic equipment. In some embodiments, a heatsink shroud 234 may enclose or at least partially enclose one or more heat generating components 205, thus enclosing or partially enclosing the area immediately adjacent a heat generating component 205.

The heatsink shroud 234 may have an opening (e.g., along the lower edge in the orientation shown in FIGS. 2-4) configured to receive freshly cooled dielectric cooling fluid 122, delivered from the third port 218, and another opening (i.e., an exit) coupled to one or more of the shroud coolant removal lines 224, which enables suction fluid to be drawn from a region in closest proximity or closer proximity to select heat generating components 205. In this way, coolant within the heatsink shroud 234 may be in fluid communication with the second port 214 with the shroud coolant removal lines 224 and optionally any intermediate tubing or conduit between the heatsink shroud 234 and the second port 214. Alternatively, the shroud coolant removal line(s) 224 may be integrally formed with one or more elements of the second port 214.

The mixed fluid may then be ejected through the third port 218 at an increased flow rate compared to natural convection alone. This amplified circulation enables targeted component-specific cooling by directing freshly cooled dielectric coolant towards specific areas within the immersion tank (e.g., shroud coolant removal lines connected directly to heatsink shrouds surrounding CPUs or GPUs).

Additionally, the distal end of the third port 218 may be coupled to a third port extension 228 that extends away from the eductor 210 and may be configured to deliver freshly cooled dielectric cooling fluid 122. The third port extension 228 may include a distribution manifold with more than one orifice configured to disburse the freshly cooled dielectric cooling fluid 122. Alternatively, the third port extension 228 may be integrally formed with one or more elements of the third port 218.

By having the shroud coolant removal line(s) 224 fluidly couple the heatsink shroud(s) 234 with the second port 214, a low pressure generated in the second port 214 by the motive fluid will be configured to draw fluid from inside the heatsink shroud(s) 234 at a much greater rate than natural convection. Dielectric cooling fluid 122 pulled into the second port, via the shroud coolant removal line(s) 224 and the heatsink shroud(s) 234 may be twice that of the motive fluid. For example, motive fluid flowing at a first rate of 0.45 m3/h may pull suction fluid at a second rate of in 0.90 m3/h, which may combine to provide a combined outlet flow at a third rate of 1.35 m3/h. In this example, the 0.45 m3/h motive fluid is available to cool the server while the balance of 0.90 m3/h suction fluid is available for enhanced cooling flow at the heat generating components 205 (e.g., CPUs and/or GPUs). This ratio of flow rates is exemplary and can be tuned to meet a variety of cooling demands. Substantially all the heat may be transferred into a net suction fluid flow from the fluid surrounding the heat generating components 205. The amplified flow in accordance with various embodiments may be used to promote high performance at the heat generating components 205. The mixture of the suction fluid with the motive fluid may result in all or substantially all the thermal energy ending up in the net flow through the heat generating electronic equipment 220 (e.g., electronic equipment 20, such as rack-mounted servers).

A suction fluid temperature exiting the heatsink shroud 234 may be warmer than the cooled dielectric fluid returned from the heat exchanger 250 into the eductor 210. Thus, the higher suction fluid temperature may slightly raise the temperature of the mixed fluid temperature leaving the eductor (i.e., the mix of the motive fluid and the suction fluid), as compared to the temperature of the motive fluid alone supplied from the heat exchanger 250. In this way, it is somewhat counter intuitive to add warmer suction fluid to the returning cooled dielectric fluid. This increase in temperature of the mixed fluid, as compared to just the temperature of the fluid from the heat exchanger might seem at first to lead to a negative result, but the profound beneficial effect of accelerating the fluid flow through the heatsinks may more than compensate for the increased mixed fluid temperature. For example, for a 600W CPU cooled by only natural convection and a lower temperature fluid (i.e., no heatsink shroud 234, shroud coolant removal lines(s) 224, or second port 214 suction fluid pulled away from the CPU) may have a convection-only case temperature TCase-1 of ˜107° C. In comparison, the same CPU provided with an amplified flow with slightly warmer fluid mixed cooling fluid exiting the eductor 210 may have an amplified-flow case temperature TCase-2 of ˜77° C. Providing a convection-only case temperature TCase-1 of ˜107° C. would not provide enough cooling for most if not all CPUs and GPUs, whilst providing the amplified-flow case temperature of ˜77° C. would provide enough cooling for most if not all CPUs.

In some embodiments, a chiller is integrated into this immersion cooling system as a secondary heat exchanger to leverage ambient temperatures for enhanced performance during cooler months of data center operation. This component may be connected in series with condensing units. The chiller may work in tandem with a condensing unit to enhance cooling performance by leveraging ambient temperatures. In cooler months (e.g., during data center operation), outside air can be used as a coolant through an open-loop or closed-loop system depending on specific design requirements. This may reduce energy consumption and increase overall efficiency.

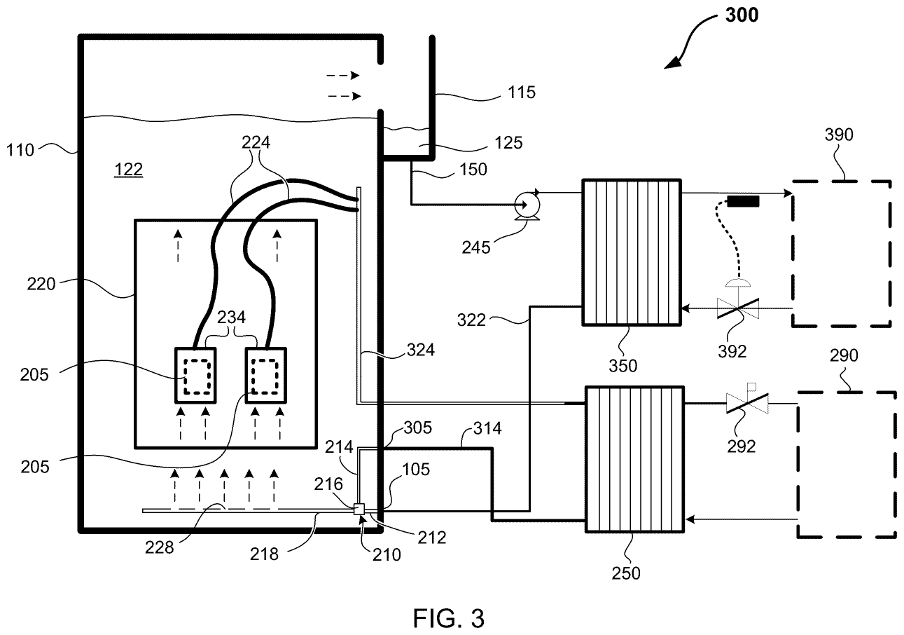

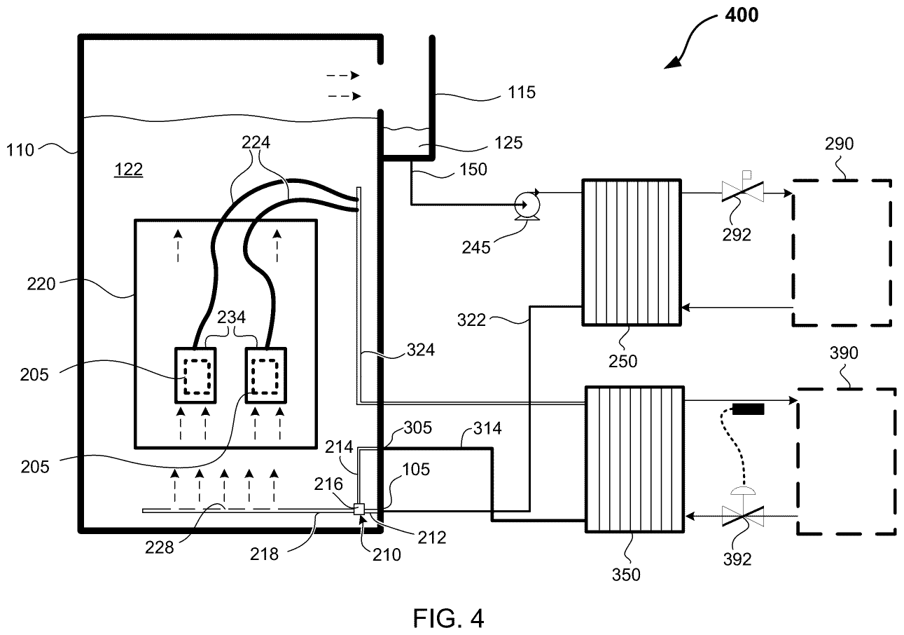

FIGS. 3 and 4 are schematic drawings of immersion cooling systems 300, 400 that include coolant flow enhancement elements in accordance with various embodiments. With reference to FIGS. 3 and 4, immersion cooling systems 300, 400 may include a second heat exchanger for removal of heat from the dielectric liquid. More particularly, the immersion cooling systems 300, 400 may include a chiller (likely based upon a vapor compression Rankine cycle) 350, combined with a condensing unit 390 that cools using a secondary coolant, such as water and/or air, the physical arrangement of the heat exchangers may take on many configurations of which two example configurations are shown. The chiller 350 is a form of heat exchanger that uses a metered flow of high pressure liquid refrigerant that undergoes a reduction of pressure across the metering device that promotes the evaporation of the refrigerant where it absorbs heat from the primary fluid (e.g., dielectric liquid, such as the heated primary circuit dielectric cooling fluid 122 or the heated second portion of the volume of dielectric cooling fluid drawn from within the heatsink shroud 234) before circulating that fluid to another element within the immersion cooling system 300, 400. This process may increase efficiency by reducing the load on the heat exchanger 250. For example, in data centers, chillers can use outside air during cooler months to reduce energy consumption.

The condensing unit 390 may be a component of a refrigeration system that includes a compressor, condenser, and fan. The condensing unit 390 may expel heat absorbed by the dielectric cooling fluid 122 from the cooled space to the outside environment. For example, condensing units may be used to discharge the heat absorbed to maintain a controlled environment. A thermostatic expansion valve (TEV) 392 may regulate the flow of coolant between the chiller 350 and the condensing unit 390, or vise-versa, based on the cooling load. The TEV 392 may maintain a desired temperature differential, measured between the coolant exiting and coolant returning to the chiller 350, by adjusting the coolant flow rate through the TEV 392. The condensing unit 390 may, via vapor compression, extract a low pressure low temperature gas (e.g., slightly super-heated) secondary coolant (e.g., refrigerant) from the second heat exchanger 350/390 and compress it into a high pressure high temperature gas which would be passed through a condenser that would cool, condense, and sub cool the inlet gas into a high pressure warm liquid that would be passed back to the second heat exchanger 350/390 (i.e., evaporator) prior to which it may undergo substantial pressure drop by means of a refrigerant metering device into a cool liquid or mostly liquid with small gas fraction mixture. Upon entering the second heat exchanger 350/390, the liquid fraction should evaporate taking in the heat from the primary coolant while becoming a low-pressure low temperature (slightly super-heated) gas. This cycle may continue so long as active heat removal is required.

Alternatively, in accordance with various embodiments, the chiller 350 and condensing unit 390 included in the immersion cooling systems 300, 400 may be replaced with a second heat exchanger. Also, alternative heat exchangers may be used instead of a chiller or condensing unit; these alternatives might include shell-and-tube designs with varying advantages (e.g., compactness) and disadvantages (e.g., pressure drop). The choice between different design options may depend on system requirements for optimal thermal management.

With reference to FIG. 3, in accordance with various embodiments, the condensing unit 390 of the immersion cooling system 300 may further cool the motive fluid that is mixed with the suction fluid pulled into the eductor 210. In the immersion cooling system 300, rather than being directed to the heat exchanger 250, the primary circuit dielectric cooling fluid 122 from the primary circuit coolant removal line 150 may be pumped through the chiller 350 by means of the pump 245. The chiller 350 may use an economizer cycle to leverage lower ambient temperatures, improving overall efficiency by pre-cooling the heated primary circuit dielectric cooling fluid 122 before it is returned to the tank 110 via a return line 322 and a distribution manifold and/or inlet port 105. The inlet port 105 may be configured to direct the supplied dielectric cooling fluid 122 (e.g., to cool one or more particular piece of heat generating electronic equipment 220), as described above regarding the immersion cooling system 200.

Additionally, in the immersion cooling system 300, rather than being coupled directly to the shroud coolant removal line(s) 224 or the heatsink shroud(s) 234, the second port 214 may receive suction fluid from the heat exchanger 250. In this embodiment, the shroud coolant removal line(s) 224 may be coupled to a shroud coolant extension line 324 that directs coolant drawn out of the heatsink shroud 234 through the heat exchanger 250 and then back through a suction fluid supply line 314 that couples with the second port 214 via a suction fluid inlet 305.

As with the earlier embodiment, for a 600W CPU cooled by only natural convection and a lower temperature fluid (i.e., no heatsink shroud 234, shroud coolant removal lines(s) 224, etc.), but using other aspects of the immersion cooling system 300, may have a convection-only case temperature TCase-1 of ˜102° C. In comparison, the same CPU provided with an amplified flow provided by the immersion cooling system 300 may have an amplified-flow case temperature TCase-2 of ˜70° C. Once again, providing the amplified-flow case temperature of ˜70° C. would provide sufficient and improved cooling for most if not all CPUs.

Alternatively, in accordance with the immersion cooling system 300, main portions of the eductor 210 (e.g., the mixing section 216) or all of the eductor 210 may be disposed outside the tank 110. This configuration provides improved accessibility and the advantage of needing one less port into the tank 110 (e.g., eliminating the suction fluid inlet 305). With the eductor 210 located outside the tank 110, the third port 118 may be coupled to or extend through the inlet port 105 from the outside.

With reference to FIG. 4, in accordance with various embodiments, the condensing unit 390 of the immersion cooling system 400 may further cool the suction fluid pulled into the eductor 210. In the immersion cooling system 400, the primary circuit dielectric cooling fluid 122 from the primary circuit coolant removal line 150 is pumped to the heat exchanger 250 by means of the pump 245, similar to that of the immersion cooling system 200. The chiller 350 may provide pre-cooling of the heated coolant shroud drawn out of the heatsink shroud 234, via the shroud coolant removal line(s) 224 and the shroud coolant extension line 324, before it is supplied to the tank 110 via the suction fluid supply line 314 that couples with the second port 214 via the suction fluid inlet 305. In this way, in the immersion cooling system 400, the second port 214 may receive suction fluid from the chiller 350.

As with the earlier embodiments, for a 600W CPU cooled by only natural convection and a lower temperature fluid (i.e., no heatsink shroud 234, shroud coolant removal lines(s) 224, etc.), but using other aspects of the immersion cooling system 400, may have a convection-only case temperature TCase-1 of ˜107° C. In comparison, the same CPU provided with an amplified flow provided by the immersion cooling system 400 may have an amplified-flow case temperature TCase-2 of ˜67° C. Once again, providing the amplified-flow case temperature of ˜67° C. would provide sufficient and improved cooling for most if not all CPUs.

Alternatively, in accordance with the immersion cooling system 400, main portions of the eductor 210 (e.g., the mixing section 216) may be disposed outside the tank 110. This configuration provides the advantage of needing one less port into the tank 110 (e.g., eliminating the suction fluid inlet 305). With the eductor 210 located outside the tank 110, the third port 118 may be coupled to or extend through the inlet port 105 from the outside.

One of skill in the art would understand that other configurations of components may be implemented to enhance the overall cooling impact. While additional elements may improve the overall cooling, the relative impact of the additional components may be marginal depending on the implemented configuration. Other configurations, such as deploying the heat exchanger 250 within the immersion coolant tank 110 may also be implemented. The suction fluid input into the eductor 210 (e.g., liquid venturi eductor) may also be thermally treated by a cooling step prior to the inlet into this device. There are several methods to cool the fluid. Two exemplary methods are described herein, but various embodiments described herein need not be limited to those two described methods. The two exemplary methods of cooling the fluid described herein are referred to as “low flow” and “high flow,” which refers to a relative flow rate of the motive fluid in suction fluid respectively. Cooling methods may include air cooling, water cooling, refrigeration cycle(s), evaporation cooling, and/or thermoelectric cooling.

In an exemplary low flow method with a chiller (e.g., 350), the lower flow rate of the “motive fluid” is cooled by the economizing chiller with vapor compression system to cool the motive fluid to a temperature well below prevailing warm ambient temperatures. In cooler or more moderate ambient temperatures, a free cooling method may be sufficient to achieve the desired fluid temperature for State Point (StPt), such as the coolant temperature supplied to the first port 212. This method may be preferable over the high flow method since a smaller portion of fluid and heat load would need to be treated by the more energy intensive chilling (i.e., vapor compression cycle). However, a disadvantage may be that to achieve a cooler temperature exiting the third port 218, the coolant temperature supplied to the first port 212 would need to be lower than that of the high flow method.

In an exemplary high flow method with a chiller, the higher flow rate “suction fluid” is cooled by the chiller 350 with vapor compression system to cool the suction fluid to a temperature well below prevailing warm ambient temperatures. In cooler or more moderate ambient temperatures, the free cooling method may be sufficient to achieve the desired fluid temperature supplied to the second port 214. This technique may cool a greater ratio of the fluid than the above technique, therefore achieving lower temperatures exiting the third port 218. However, a disadvantage may be that a greater amount of thermal energy must be treated with the energy intensive vapor compression cycle. This may create a need for a larger chiller with associated higher power demand.

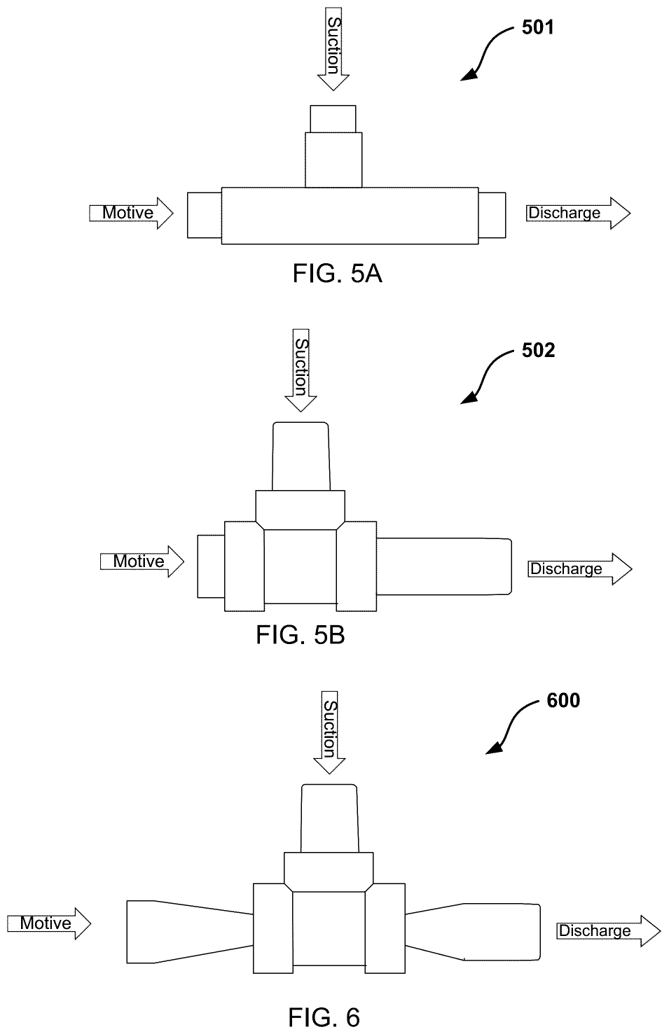

FIGS. 5A and 5B illustrate exemplary eductors 501, 502, both in the form of liquid venturi eductors for use in various embodiments. As shown in FIGS. 5A and 5B, motive fluid may be directed through a first port (e.g., left side in the orientations shown) above certain flow rates; a pressure drop through the eductor may result in a suction that pulls suction fluid into the second port (e.g., top side in the orientations shown) to mix with the motive fluid; and the mixed fluid may be discharged through the third port (e.g., right side in the orientations shown).

In alternative embodiments, eductors may be implemented using other types such as ejector-type devices that use a high-velocity jet stream or vortex generators creating swirling motion within the mixing chamber for enhanced fluid circulation and heat transfer. Spiral-shaped educators with multiple turns increasing in diameter to increase flow rates are also possible embodiments of this invention.

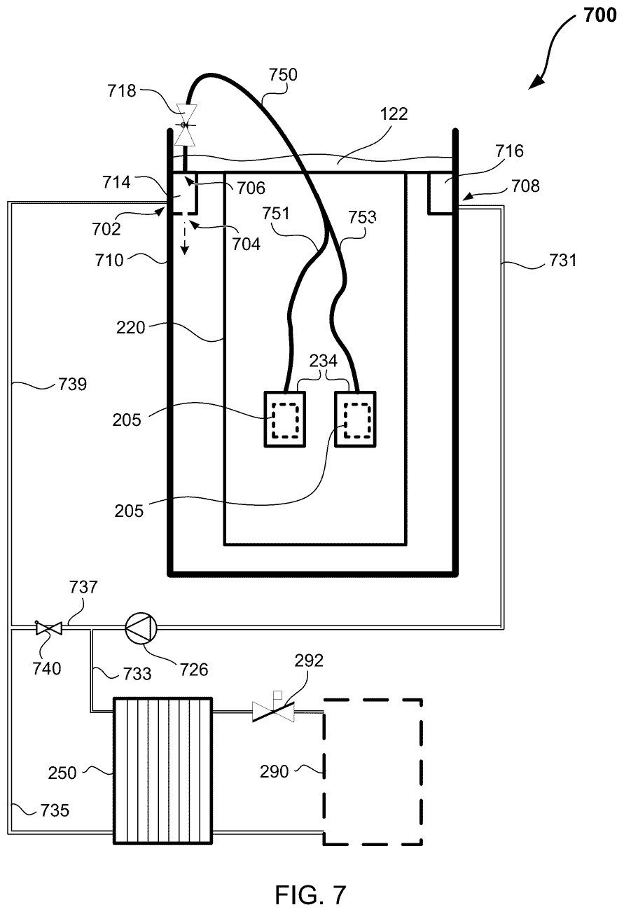

FIG. 6 illustrates an exemplary eductor 600 in the form of a nozzle/diffuser eductor for use in various embodiments. As shown in FIG. 6, motive fluid may be directed through a nozzle (e.g., left side in the orientations shown), which is configured to convert pressure energy of the motive fluid into velocity energy. An increased pressure drop through the eductor may result in a greater suction that pulls suction fluid into the second port (e.g., top side in the orientations shown) to mix with the motive fluid. The mixed fluid may be discharged through the diffuser (e.g., right side in the orientations shown) converting pressure energy therein into a higher velocity energy.

Various embodiments of eductors may be designed with different configurations and materials for optimal performance in diverse applications. For instance: a liquid venturi-type device may use spiral-shaped passages; an ejector-based design may employ high-velocity jet streams; vortex generators might create swirling motion within the mixing chamber to enhance fluid circulation. Additional embodiments of eductors may include using multiple inlet ports to draw suction fluids from different areas inside the immersion tank, incorporating separate sections or branches in second port extensions connecting individual heat generating components with their respective shroud coolant removal lines to create a network of fluid connections for targeted cooling control at each component level, employing alternative flow-enhancing devices such as vortex generators within the mixing chamber to create a swirling motion and enhance dielectric circulation, and designing eductors using different materials, such as steel or strong plastics compatible with the chosen dielectric fluid, suitable for specific applications.

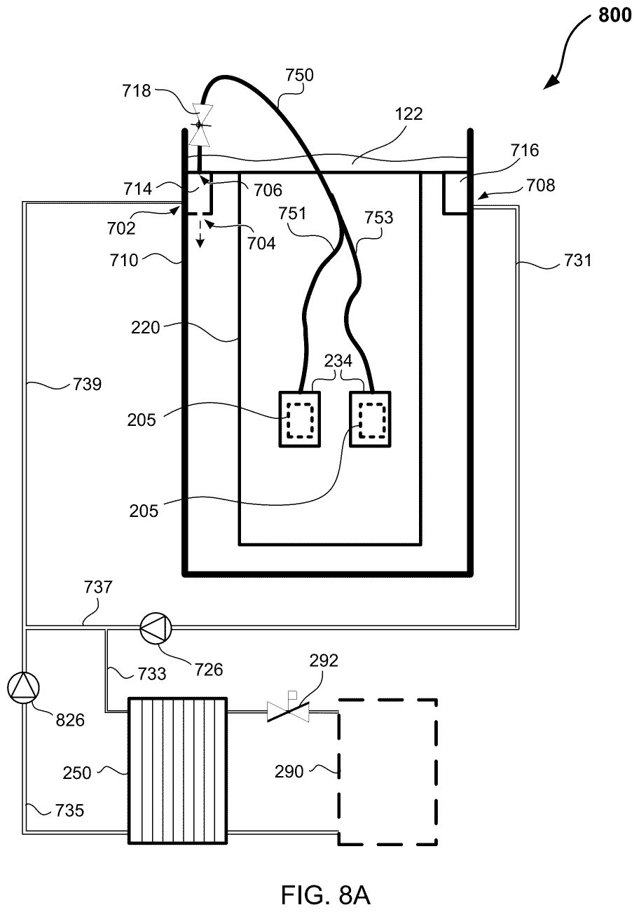

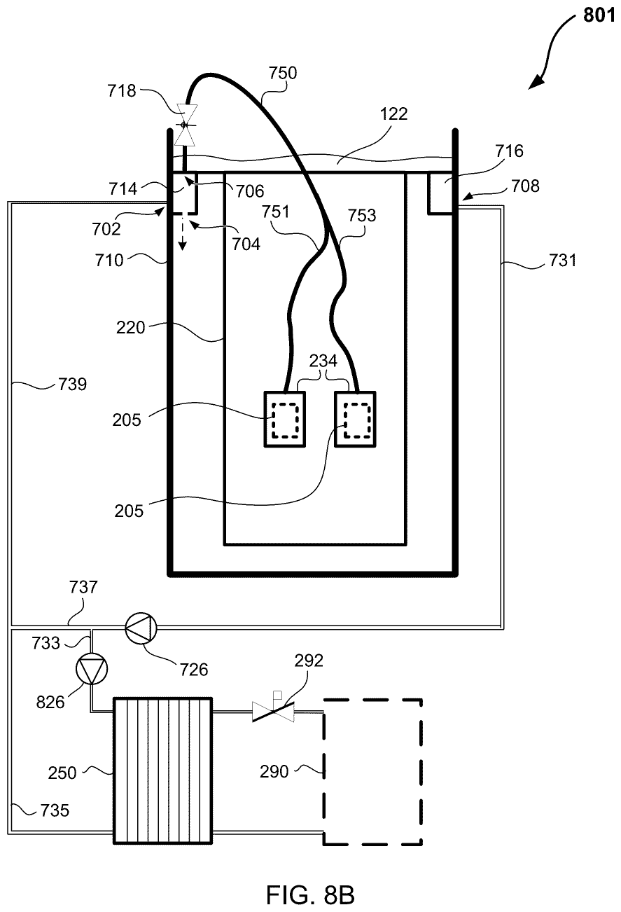

FIGS. 7-8B are schematic block diagrams that illustrate immersion cooling systems 700, 800, 801 that include an immersion coolant tank 710, a heat exchanger 250, a first pump 726, coolant circulation lines 731, 733, 735, 737, 739 that couple those elements in a fluid circuit, and at least one bypass flow control device configured to control coolant flow that bypasses the heat exchanger 250, in accordance with various embodiments. The bypass flow control device(s) may be configured to control bypass flow around (i.e., avoiding) the heat exchanger by restricting flow (e.g., using a valve or other controlling device) or motivating flow (e.g., using a second pump), and may control side stream flow through the heat exchanger 250. The at least one bypass flow control device may include a flow restriction valve 740 as demonstrated in FIG. 7 and/or a second pump 826 as demonstrated in FIGS. 8A and 8B. The immersion coolant tank 710 may include a supply manifold 714 configured to distribute colder dielectric cooling fluid 122 supplied to the tank 710 and a return manifold 716 configured to release heated dielectric cooling fluid 122 from the tank 710. The immersion coolant tank 710 includes an open interior volume configured to hold heat generating electronic equipment 220, with one or more heat generating components 205, at least partially submerged in dielectric cooling fluid 122. The immersion coolant tank 710 may also include many of the features and design elements described above for the immersion coolant tank 110.

The heat exchanger 250 is configured to receive a first portion of the dielectric cooling fluid 122 released from the immersion coolant tank (e.g., from the return manifold 716). The heat exchanger 250 is configured to cool and return the first portion of the dielectric cooling fluid 112 to the immersion coolant tank 710.

The first pump 726 is configured to move dielectric cooling fluid 122 between the outlet port 708 and the inlet port 702 via the coolant circulation lines 731, 733, 735, 737, 739. Once the dielectric cooling fluid 122, at least partially cooled by the heat exchanger 250, passes through the inlet port 702 and enters the open interior volume of the immersion coolant tank 710, it mixes with the rest of the dielectric cooling fluid 122 already present in the tank 710, and eventually a heated portion of the dielectric cooling fluid 122 will pass through the outlet port 708, starting another cycle of cooling and resupply. In particular, the first pump 726 may draw dielectric cooling fluid 122 from the return manifold 716 and recirculate the drawn dielectric cooling fluid 122 to the supply manifold 714, via the heat exchanger 250 and/or a coolant bypass line 737. The flow path and rate of the dielectric cooling fluid circulated in the coolant circulation lines 731, 733, 735, 737, 739 may be controlled by one or more bypass flow control device (e.g., a control valve 740 or a second pump 826). The bypass flow control device(s) may be located downstream of the first pump 726. In various embodiments, the bypass flow control device may be a control valve 740, which may be fixed valve (e.g., a choke assembly) or variable valve (e.g., a motorized control valve).

The coolant circulation lines may include coolant return lines 731, 733, coolant supply lines 735, 739, and a coolant bypass line 737. The coolant return lines 731, 733 fluidly couple the outlet port 708 of the immersion coolant tank 710 to the heat exchanger 250. The coolant supply lines 735, 739 fluidly couple the heat exchanger 250 to the inlet port 702 of the immersion coolant tank 710. An upstream end of the coolant bypass line 737 may be disposed downstream of the first pump 726 at a branch junction with the second coolant return line 733. A downstream end of the coolant bypass line 737 may be disposed further downstream of the first pump 726 at a branch junction with the first and second coolant supply lines 735, 739. In this way, the coolant bypass line 737 couples the first coolant return line 731 to the second coolant supply line 739, providing an alternate branch that bypasses the second coolant return line 733, the heat exchanger 250, and the first coolant supply line 735. In particular, the coolant bypass line 737 is configured to enable a second portion of the warmer dielectric cooling fluid to bypass the heat exchanger before being delivered to the inlet port 702. In this way, the first portion of the warmer dielectric cooling fluid may be directed to the heat exchanger 250 and the second portion of the warmer dielectric cooling fluid bypasses the heat exchanger 250. The coolant circulation lines may consist of flexible tubing.

In various embodiments, the inlet port 702 may provide an entrance to the immersion coolant tank 710 for the colder dielectric cooling fluid 122 cooled down by the heat exchanger 250. In some embodiments, the inlet port 702 may more particularly provide the entrance to a supply manifold 714 configured to receive and distribute the colder dielectric cooling fluid 122 into the immersion coolant tank.

The supply manifold 714 may include one or more outlets ports for the distribution of the received dielectric cooling fluid 122. For example, the supply manifold 714 may include one or more bulk supply port(s) 704 that deliver a first portion of the received dielectric cooling fluid to a general area within the tank (e.g., the bottom of the tank). The supply manifold 714 may also include one or more directed supply port(s) 706 that deliver a second portion of the received dielectric cooling fluid to an area within the immersion coolant tank that is immediately adjacent to at least one heat generating component 205 of the heat generating electronic equipment 220. The supply manifold 714 within the immersion coolant tank 710 may take various forms depending on specific design constraints or application demands. In some cases, the supply manifold 714 may have a single bulk port delivering dielectric fluid directly into the open interior volume; in other instances, multiple ports might be employed for more precise control over local temperature management around individual components.

In various embodiments where multiple components require simultaneous temperature control due to high-heat flux requirements or specific thermal constraints, the coolant supply lines may incorporate features such as separate manifolds dedicated to each component. In other configurations, adjustable valves may be integrated into manifold designs for precise control over fluid flow and pressure management within individual branches.

The bulk supply port(s) 704 may include an array of variable geometry ports (e.g., constant flow rate taps) configured to handle a portion of the received colder dielectric cooling fluid intended to flow through the immersion coolant tank 710. A flow rate through the bulk supply port(s) 704 may vary as a function of the supply pressure present in the supply manifold 714, as supplied by the dielectric cooling fluid delivered from the coolant supply lines 735, 739. The bulk supply port(s) 704 may include lines (i.e., tubes or other conduit) extending between the supply manifold 714 and the general area within the tank where the first portion is intended to be delivered (e.g., the bottom of the tank). In various embodiments, the constant flow taps of the bulk supply ports 704 may maintain a predetermined flow rate regardless of supply manifold 714 pressure (i.e., range of 0.03 to 1.0 MPa), to feed the dielectric cooling fluid 122 through the coolant circulation lines (e.g., 731, 733, 735, 737, 739) to the heat generating electronic equipment 220, so that the dielectric cooling fluid 122 may be delivered to the heat generating components 205, which may be high heat flux items (e.g., CPU(s), etc.).

The directed supply port(s) 706 may be variable flow ports (e.g., variable flow rate taps) configured to handle the remaining portion of the received colder dielectric cooling fluid intended more specifically to cool one or more particular heat generating electronic equipment 220 or components thereof (e.g., 205). The directed supply port(s) 706 may be coupled to directed coolant supply lines 750, 751, 753 (i.e., tubes or other conduit) extending between the directed supply port(s) 706 and the area within the immersion coolant tank 710 that is immediately adjacent to at least one piece of heat generating electronic equipment 220 (e.g., configured to flow across and/or onto a surface of the heat generating component 205).

The directed coolant supply lines 750, 751, 753 may be configured such that a first directed coolant supply line 750 is coupled to the directed supply port 706 and the second and third directed coolant supply lines 751, 753 branch off the first directed coolant supply line 750. In certain embodiments, additional features may be incorporated into the design of the coolant supply lines 750, 751, 753 to enhance performance or simplify installation procedures, such as a built-in pressure gauge for real-time monitoring of system pressures and facilitating adjustments, integrated fittings with adjustable compression nuts for secure connections without compromising tubing flexibility, and reinforced sections for added strength in areas prone to high stress. In another embodiment, multiple coolant supply lines 750, 751, 753 may be connected in parallel or series configurations, depending on specific application requirements, enabling increased cooling capacity and more precise control over fluid circulation within the tank.

Various embodiments may include heatsink shrouds 234 at least partially enclosing the at least one heat generating component 205 of the heat generating electronic equipment 220. Inside the heatsink shrouds 234 may include guides or channels for directing received dielectric cooling fluid 122. The heatsink shroud 234 may be a separate component added to or mounted on a heat generating component 205. Alternatively, the heatsink shroud 234 may be a feature in and of the heat generating component 205 itself (or a portion thereof). Either way, the heatsink shroud 234 may enable the heat generating component 205 or a portion thereof to receive dielectric cooling fluid 112, which may then exit the heatsink shroud 234 into a housing/chassis of the heat generating electronic equipment 220 at large and/or the inside of the tank 110 at large. The heatsink shroud 234 may be coupled to one or more of the directed coolant supply lines 750, 751, 753. For example, the second and third directed coolant supply lines 751, 753 effectively, may be coupled to ports on separate heatsink shrouds 234. In this way, the portion of the colder dielectric cooling fluid delivered immediately adjacent to the at least one heat generating component 205 may be delivered within the heatsink shroud 234 which covers a heat generating component 205. The heatsink shroud 234 may have an opening (e.g., inlet port) configured to receive freshly cooled dielectric cooling fluid 122, delivered from the directed coolant supply lines 750, 751, 753. The heatsink shroud 234 may include one or more additional openings (i.e., along one or more edges in the orientation shown in FIGS. 2-4 and 7-8B) open to the more general dielectric cooling fluid 122 inside the immersion coolant tank 710. This enables delivery of colder dielectric cooling fluid 122 to a region in closest proximity or closest proximity to a select heat generating component 205 (i.e., immediately adjacent).

In various embodiments, the directed supply port(s) 706 may be an array of constant flow taps coupled to a flow control device 718 (e.g., a flow valve, constant flow device, constant flow valve, a plurality of control valves, etc.) configured to control the flow of the of the second portion of the received dielectric cooling fluid through the directed coolant supply lines 750, 751, 753. The flow control device 718 may be coupled to the supply manifold 714, such as between the directed supply port 706 and the initial directed coolant supply line 750. Alternatively, or additionally, one or more flow control device 718 may be located in-line in one or more of the directed coolant supply lines 750, 751, 753. In some embodiments, one or more of the flow control devices 718 may each be coupled to the supply manifold and/or the directed coolant supply lines 750, 751, 753 with quick connect fittings. Such quick connect fittings may include valves that automatically actuate upon the coupling and decoupling operation. The flow control device 718 may ensure that a constant flow volume is provided to the directed coolant supply lines 750, 751, 753, regardless of the pressure or flow that is provided in the supply manifold 714. The flow control device 718 may be selectable to match the specified flow to a particular one or more of heat generating electronic equipment 220 to which it is connected, or the flow control device 718 may have any number of preset flows that may be adjusted to supply the specified flow of a particular heat generating electronic equipment 220 or more particularly the heat generating component 205 to which it delivers fluid. Any of a plurality of flow control devices may be considered suitable as the flow control device 718 in this disclosure.

In various embodiments, the outlet port 708 may provide a dielectric cooling fluid exit from a return manifold 716 configured to release warmer dielectric cooling fluid from the immersion coolant tank. The return manifold 716 may be similar to the return reservoir (e.g., 115) described with regard to FIGS. 2-4. The return manifold 716 may be designed with sloping surfaces to facilitate easy drainage and prevent accumulation of liquid within the tank. The return manifold 716 may also incorporate various shapes or geometries optimized for efficient fluid flow distribution throughout the immersion coolant tank. For example, rectangular or cylindrical designs may be employed in certain embodiments where space constraints are a concern.

In accordance with various embodiments, one or more flow restriction devices may be used in the immersion cooling system for heat generating electronic equipment, playing a useful role in controlling flow paths and/or regulating fluid pressure drops within specific sections of the circulation lines to ensure optimal performance and efficiency. In various embodiments, the flow restriction device may take on different forms depending on the application requirements. For example, the flow restriction device may be implemented as an orifice plate with precision-machined holes that restricts the passage of dielectric cooling fluid while maintaining a consistent pressure drop across the system. This design is particularly useful in applications where precise control over coolant distribution and flow rates are useful to ensure uniform heat transfer between components.

In another embodiment, the flow restriction device may be designed as an adjustable valve with multiple stages or sections that allow for fine-tuning of fluid resistance based on specific operating conditions. For instance, a butterfly valve may be used in combination with a needle valve to create a hybrid design offering both coarse and precise control over pressure drops. Such valves may be adjustable, either manually or through automation.

In yet another embodiment, the flow restriction device may take the form of an electronic throttle controller connected directly to sensors monitoring temperature, pressure, or other parameters within the system. This allows for real-time adjustments based on changing operating conditions, ensuring optimal performance under varying scenarios such as changes in ambient temperatures or component heat generation rates.

Furthermore, multiple flow restriction devices may be used together in series and/or parallel configurations depending on specific application requirements. For example, a combination of an adjustable valve with precision-machined holes may provide coarse control over pressure drops while also allowing for fine-tuning based on real-time system conditions.

With reference to FIG. 7, in accordance with various embodiments, the immersion cooling system 700 includes at least one bypass flow control device for controlling bypass flow around the heat exchanger 250 in the form of the flow restriction valve 740, which is disposed downstream of the first pump 726. In some embodiments, the flow restriction valve 740 is disposed in-line in the coolant bypass line 737. The flow restriction valve 740 may be any valve configured to control the flow rate of fluids by adjusting the size of the flow passages. For example, the flow restriction valve 740 may be a choke valve, globe valve, ball valve, gate valve, needle valve, butterfly valve, plug valve, diaphragm valve, and/or pinch valve. The flow restriction valve 740 may be a motorized valve. Alternatively, the intersection of the first coolant return line 731, the second coolant return line 733, and the coolant bypass line 737 may include a T-coupling with a three-way valve, such as a three-way ball valve, three-way globe valve, diverter valve, three-way plug valve, mixing valve, and/or three-way butterfly valve. These types of three-way valves allow for precise control and adjustment of flow ratios at the intersection of pipes, enabling efficient distribution of fluids.

A flow restriction valve 740 may be adjustable to manage the flow of dielectric cooling fluid 122. The flow restriction valve 740 creates a pressure differential across the coolant bypass line 737 to produce a desired flow rate through the heat exchanger 250. The heat exchanger 250 may be used to cool the warmer dielectric cooling fluid 122 from the outlet port 708 with a secondary fluid (i.e. water, refrigerant, etc.). The flow restriction valve 740 and the heat exchanger 250 may form a parallel flow network. In this exemplary embodiment, the parallel flow may converge at the intersection of the first coolant supply line 735 and the coolant bypass line 737 with the second coolant supply line 739 and travel to the inlet port 702.

In this exemplary embodiment, the immersion cooling system 700 may use a single pump, namely the first pump 726, while reducing the total pump power associated with forcing all the fluid through the heat exchanger 250. This may be accomplished by the creation of pressure differential across the flow restriction valve 740. The exact differential that may be needed to create the desired side stream flow through the heat exchanger 250 may be achieved with adjustments to the flow restriction valve 740. In turbulent flow regimes (such as typically found within the heat transfer surface of a heat exchanger) the pressure head requirements increase by the square of the flow ratio. That is to say if the flow doubles the pressure head requirement increases by factor of 4 times the value associated with the lower flow. By having essentially two flow circuits; through (i) coolant bypass line 737 via the flow restriction valve 740, and/or (ii) the heat exchanger 250 the excessive flow and excessive power associated with the otherwise total flow through the heat exchanger 250 may be avoided thereby reducing pumping power and electrical energy consumption.

With reference to FIGS. 8A and 8B, in accordance with various embodiments, the immersion cooling systems 800, 801 may include at least one bypass flow control device for controlling bypass flow around the heat exchanger 250 in the form of a flow motivation device like the second pump 826 disposed downstream of the heat exchanger 250 in the first coolant supply line 735. The embodiments illustrated in FIGS. 8A and 8B are similar to the immersion cooling system 700 illustrated in FIG. 7. For sake of brevity, many of the elements that are illustrated and described with regard to FIG. 7 are not described again. In the immersion cooling system 800 of FIGS. 8A and 8B, the dielectric cooling fluid 122 may be pulled from the outlet port 708 through the first coolant return line 731, through the first pump 726, and then discharged into the second coolant supply line 739. Some distance downstream of the first pump 726, a branch coupling may provide a branch (side stream) to the heat exchanger 250.

With reference to FIG. 8A, in accordance with various embodiments and particularly the immersion cooling system 800, the second pump 826 (e.g., a flow device or flow motive device) may be disposed on the inlet side (i.e., downstream) of the heat exchanger 250, such as in-line along the first coolant supply line 735. With reference to FIG. 8B, in accordance with various embodiments and particularly the immersion cooling system 801, the second pump 826 may be disposed on the inlet side (i.e., upstream) of the heat exchanger 250, such as in-line along the second coolant return line 733. In various embodiments, the second pump 826 may be either variable or fix speed. Downstream of the second pump 826, the flow may converge at another branch joint and travel to the inlet port 702.

Some embodiments may include more than one or redundant elements for controlling bypass flow around the heat exchanger 250. For example, the system may include flow restriction valve 740, as described above regarding FIG. 7, as well as a flow motivation device like the second pump 826 as described above regarding FIGS. 8A and/or 8B. The elements for controlling bypass flow may include adjustable valves, fixed restrictors, or even passive components like constrictions in tubing diameter.

While the embodiments illustrated in the figures show the supply manifold 714 and the return manifold 716 located internal to the immersion coolant tank 710, alternative embodiments may include such elements located external to the main portions of the immersion coolant tank 710.

In various embodiments, the inlet port of an immersion coolant tank is a useful component in ensuring efficient and effective heat transfer within various electronic equipment configurations. In various embodiments, the inlet port may be designed as a single point for receiving dielectric fluid from multiple sources, such as pumps or valves, allowing for centralized control overflow rates and pressure management. This design enables optimal distribution of coolant to different areas within the tank while minimizing dead zones and ensuring uniform thermal gradients across various components.

In various embodiments, the inlet port may be configured with a branching manifold system that allows separate flows from multiple sources to enter distinct regions or compartments within the immersion coolant tank. For instance, one branch may supply cooler dielectric fluid directly into an area surrounding heat-generating electronic equipment for enhanced cooling performance, while another branch may supply warmer dielectric fluid to other areas of the tank where thermal gradients are less useful.

In various embodiments, multiple inlet ports may be used in a single immersion coolant tank, allowing different components or regions within the system to receive separate and distinct flows. This design may enable flexibility in accommodating various electronic equipment configurations by providing individualized cooling solutions for each component while minimizing overall complexity of the circulation lines.

Furthermore, embodiments may include adjustable valves at the inlet port level that enable real-time adjustments based on temperature sensors' readings from different areas within the tank or external environmental conditions.

In various embodiments, a direct flow supply manifold may be integrated into an immersion coolant system to provide targeted cooling for specific components. This design may allow precise control over fluid distribution and pressure management by directing cooler dielectric fluids directly towards heat-generating electronic equipment while maintaining optimal thermal gradients across other areas of the tank.

Additionally, embodiments may include bypass lines or diverting valves that enable flow redirection in response to component failure scenarios or maintenance operations. The bypass lines and diverting valves may be controlled and configured to regulate the proportions of coolant directed to the direct flow supply manifold and the tank bulk supply manifold in response to system operational needs.

The direct flow supply manifold may be configured to distribute cold dielectric cooling fluid from a heat exchanger or other source directly into areas within an immersion coolant tank that are in close proximity to one or more heat generating components of electronic equipment. In various embodiments, the direct flow supply manifold may be configured as a separate component connected between the circulation lines and the area where the coolants meet with the hotspots on the surface of these devices.

In some implementations, multiple branches within this manifold may allow for independent control over coolant distribution to different areas or components, enabling fine-tuned temperature management. For instance, one branch may be dedicated solely to a high-power component requiring more aggressive cooling while another branch is reserved exclusively for lower-powered components that may tolerate less intense heat transfer.

In other embodiments, the direct flow supply manifold may incorporate adjustable valves and/or diverting mechanisms allowing real-time adjustments based on thermal gradients within the tank. This may enable optimal coolant distribution in response to changing operating conditions or varying component temperatures. Furthermore, some implementations may incorporate sensors monitoring temperature fluctuations at specific points along this branch of circulation lines for further fine-tuning.

In accordance with various embodiments, the manifolds may be designed to incorporate features such as: (1) curved channels for improved fluid mixing; (2) strategically placed baffles to reduce turbulence, promote laminar flow, or enhance heat transfer between coolants and hotspots.

In certain embodiments where the immersion coolant tank is designed with multiple compartments or chambers, separate manifolds might serve each compartment independently. In such cases, individualized control over dielectric fluid flow and temperature within these sub-chambers may be achieved through dedicated pump systems, valves, and/or sensors tailored to specific cooling requirements.

The diverting valve is a useful component in certain immersion cooling systems that enables precise control over coolant distribution and flow rates within various areas of the tank. In various embodiments, a single diverter valve may be used to direct first portion of cooler dielectric fluid from the heat exchanger into the direct flow supply manifold for immediate delivery to hotspots adjacent to specific components or devices requiring enhanced cooling performance. Meanwhile, the second portion of this cooled-down coolant is redirected through another branch towards tank bulk supply manifolds that distribute it throughout other regions within the immersion coolant tank.

In various embodiments, multiple diverting valves may be employed in series and/or parallel configurations for even greater control over fluid flow rates between different areas of the system. For instance, a primary diverter valve may direct 70% of cooled-down dielectric cooling fluid to the direct flow supply manifold while another secondary diverter valve diverts an additional 30% towards tank bulk supplies.

In various embodiments, adjustable diverting valves may be used in conjunction with sensors and control systems that monitor temperature gradients within specific areas or components. These adjustments enable real-time optimization of coolant distribution based on actual thermal demands from the heat generating equipment being cooled. Furthermore, certain embodiments may incorporate bypass lines to ensure continued system operation even during pump failure scenarios.

In a more complex embodiment, multiple diverting valves may be integrated into separate branches for each component within an immersion cooling tank. This may allow individualized control over coolant flow rates and temperatures in response to specific thermal requirements of various components or devices being cooled. In such cases, the diverter valves may also interact with other system elements like pumps, heat exchangers, and sensors through a networked architecture.

In various embodiments, diverting valve configurations may be designed for use within immersion cooling systems that employ multiple coolant tanks in parallel to ensure redundancy and scalability purposes. This may enable seamless switching between different tank branches during maintenance or component failure scenarios without disrupting overall system operation.

In various embodiments, an auxiliary pump may be included on a parallel return line of the first pump for increased flow rate or redundancy purposes during component failure scenarios; this setup may ensure continued system operation even when one pump fails or needs to be taken offline for maintenance. The bypass branch line may be further modified to include a swing check valve that prevents backflow from entering the direct supply manifold and allows fluid flow into it only in case of primary pump failure.

In various embodiments, one or more bypass branch lines may be included that serve as backup path(s) during failure scenarios or maintenance operations when draining/refilling dielectric fluid from the immersion coolant tank, pumps, valves, or other elements. This ensures continued operation with minimal downtime and reduces potential risks associated with sudden component failures due to inadequate cooling conditions.

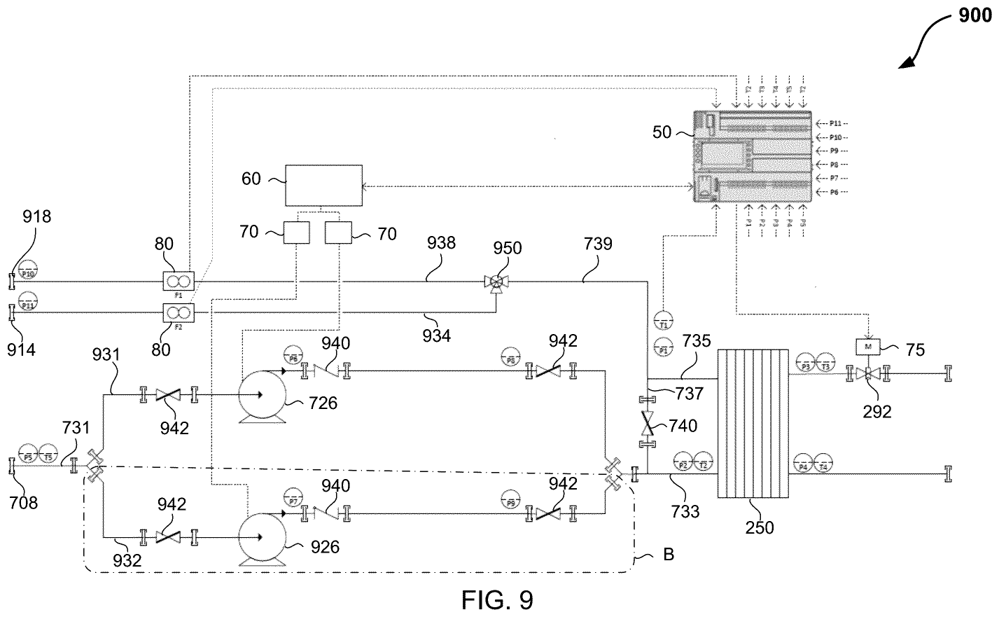

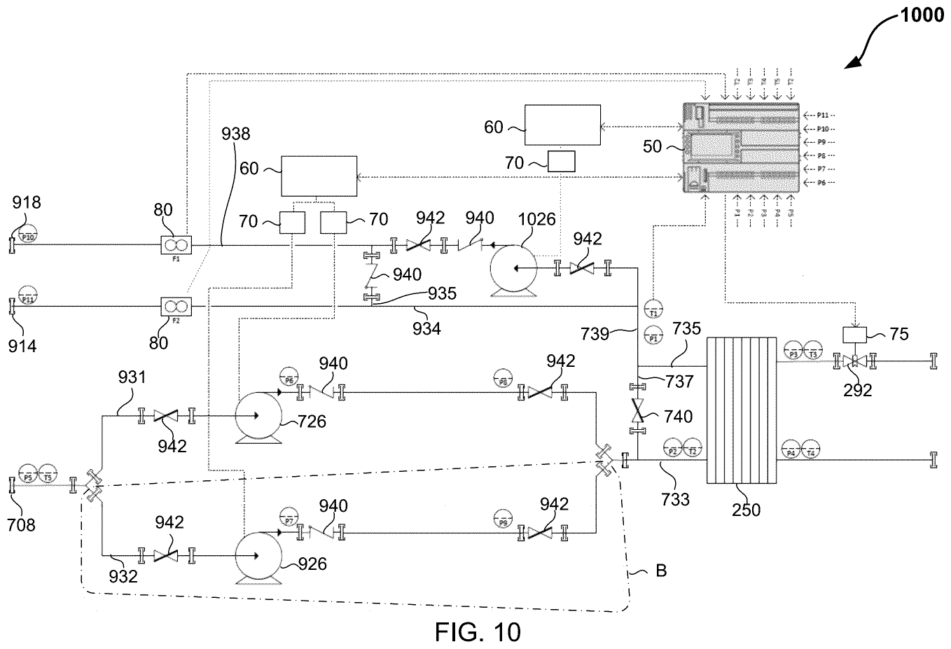

FIGS. 9 and 10 are schematic block diagrams that illustrate immersion cooling systems 900, 1000 that include a branching flow path configured to deliver cooler dielectric cooling fluid 122 to different supply manifolds, in accordance with various embodiments. The embodiments illustrated in FIGS. 9 and 10 are similar to the immersion cooling system 700 illustrated in FIG. 7. For sake of brevity, many of the elements that are illustrated and described with regard to FIG. 7 are not described again. The immersion cooling systems 900, 1000 are configured to be coupled to an immersion coolant tank (e.g., 110, 710), although not illustrated in FIGS. 9 and 10. In accordance with various embodiments, the immersion cooling systems 900, 1000 or elements thereof may be incorporated into any or all of the earlier embodiments described above.

With respect to FIGS. 9 and 10, similar to immersion cooling systems 700, 800, 801, the immersion cooling systems 900, 1000 may include a first coolant return line 931 coupled to the outlet port 708 of the immersion coolant tank (e.g., 110, 710) and including the first pump 726. In accordance with various embodiments the first coolant return line 931 may also include one or more additional valves, such as one or more swing check valve 940 and/or butterfly valves 942, positioned upstream and downstream of the first pump 726 for controlling fluid flow there through.

In accordance with various embodiments, the first coolant return line 931 portion of the system, with the included first pump 726 and valves 940, 942, may include a redundant branch B including an auxiliary coolant return line 932 that similarly includes and auxiliary pump 926 and auxiliary valves 940, 942.

In accordance with various embodiments, the inlet port of the immersion coolant tank (e.g., 710) may include a tank bulk supply manifold 914 and a direct flow supply manifold 918. Thus, rather than the single second coolant supply line 739 feeding colder dielectric cooling fluid (e.g., 122) to a single inlet port (e.g., 702), the immersion cooling systems 900, 1000 may have the second coolant supply line 739 branch into a direct flow supply line 938 and a tank bulk flow supply line 934. The direct flow supply manifold 918 may be configured to receive a first portion of the colder dielectric cooling fluid received from the direct flow supply line 938 and distribute the first portion of the colder dielectric cooling fluid to a first area within the immersion coolant tank that is immediately adjacent to at least one heat generating component of the heat generating electronic equipment (e.g., immediately adjacent a heat generating component 205, which is optionally inside the heatsink shroud 234). The tank bulk supply manifold 914 may be configured to receive a second portion of colder dielectric cooling fluid received from the tank bulk flow supply line 934 and distribute the second portion of the colder dielectric cooling fluid to a second area within the immersion coolant tank that is remote from the first area (e.g., a more generally region inside the tank, such as the bottom).

With reference to FIG. 9, in accordance with various embodiments, the immersion cooling system 900 may have the second coolant supply line 739 include a diverting valve 950 for directing the first portion of the colder dielectric cooling fluid to the direct flow supply manifold 918 (via the direct flow supply line 938) and for directing the second portion of the colder dielectric cooling fluid to the tank bulk supply manifold 914 (via the tank bulk flow supply line 934). The diverting valve 950 may be an adjustable valve that is fixed, manually adjusted, or automatically adjusted.

With reference to FIG. 10, in accordance with various embodiments, the immersion cooling system 1000 may include a direct flow control pump 1026 along a branch line from the second coolant supply line 739. Thus, like the immersion cooling system 900, which included a branch in the supply lines, the immersion cooling system 1000 may similarly include a branch where the second coolant supply line 739 branches into the direct flow supply line 938 and the tank bulk flow supply line 934. The direct flow control pump 1026 is configured to control a flow ratio of the first portion of the colder dielectric cooling fluid that flows to the direct flow supply manifold 918 (via the direct flow supply line 938) and the second portion of the colder dielectric cooling fluid that flows to the tank bulk supply manifold 914 (via the tank bulk flow supply line 934).

In accordance with various embodiments, the coolant supply lines may include a bypass branch line 935 connecting the direct flow supply line 938 to the tank bulk flow supply line 934 in cases the direct flow control pump 1026 is inoperable. The bypass branch line 935 may provide a bypass for flow to avoid the direct flow control pump 1026. The bypass branch line 935 may include a swing check valve 940, or other one-way valve, for controlling a flow to the direct flow supply line 938 from the tank bulk flow supply line 934. The swing check valve 940 on the bypass branch line 935 may allow fluid flow into the direct flow supply manifold 918 should the direct flow control pump 1026 fail whilst the other pumps (e.g., 726, 826, 926) remain operational. In this way, the swing check valve 940 on the bypass branch line 935 may prevent a flow from the tank bulk flow supply line 934 to the direct flow supply line 938.

In accordance with various embodiments, any one of the pumps (e.g., 245, 726, 826, 926) and/or valves (292, 392, 718, 740, 950), may be controlled by a processor 50 (e.g., a programmable logic controller) or other similar computing device. The processor 50 may be disposed outside the immersion coolant tank (e.g., 110, 710) or almost anywhere using a wired and/or wireless connection to the component(s) it controls. The processor 50 may control the pumps using a variable frequency drive 60 and motor starter protectors 70 for independently varying the speed of the pumps individually or collectively. Also, the processor 50 may control one or more other motor 75 for opening, closing, or varying valves (e.g., 292). Additionally, the processor 50 may receive inputs from one or more flow meters 80, one or more temperature sensors (e.g., T1-T5), and/or one or more pressure sensors (e.g., P1-P11), which inputs may be used for adjusting flow rates.

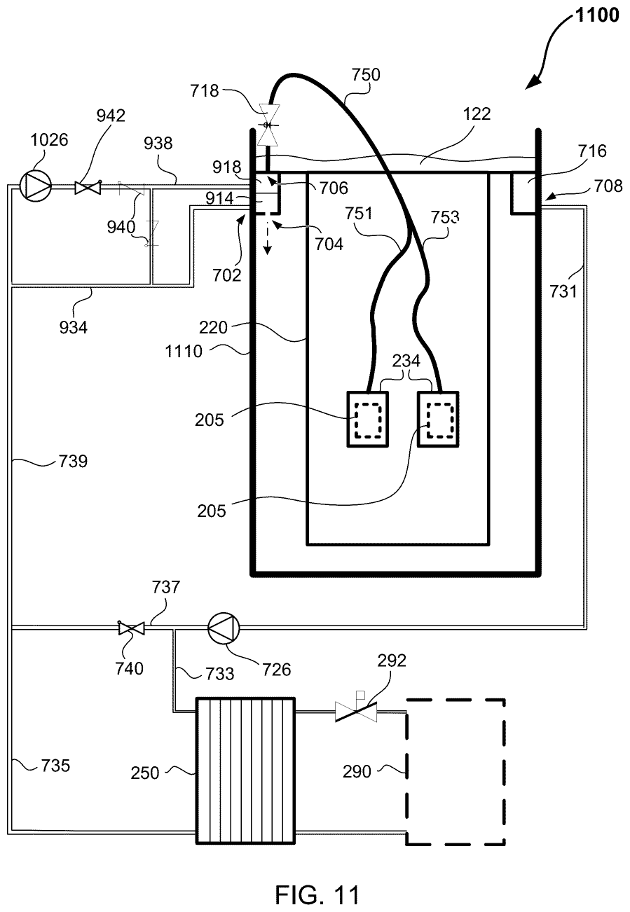

FIG. 11 is a schematic block diagram that illustrates an immersion cooling system 1100 that includes a branching flow path configured to deliver cooler dielectric cooling fluid 122 to different supply manifolds, in accordance with various embodiments. The embodiment illustrated in FIG. 11 is similar to the immersion cooling system 700 illustrated in FIG. 7. For sake of brevity, many of the elements that are illustrated and described with regard to FIG. 7 are not described again. The immersion cooling system 1100 is configured to be coupled to an immersion coolant tank 1110. In accordance with various embodiments, the immersion cooling system 1100 or elements thereof may be incorporated into any or all of the earlier embodiments described above.

With reference to FIG. 11, in accordance with various embodiments, the immersion cooling system 1100 includes the second coolant supply line 739 receiving coolant from the intersection of the first coolant supply line 735 and the coolant bypass line 737. In accordance with various embodiments, the second coolant supply line 739 may branch into a direct flow supply line 938 and a tank bulk flow supply line 934.

The direct flow supply manifold 918 may be configured to receive a first portion of the colder dielectric cooling fluid received from the direct flow supply line 938 and distribute the first portion of the colder dielectric cooling fluid to a first area within the immersion coolant 1110 tank that is immediately adjacent to at least one heat generating component of the heat generating electronic equipment (e.g., immediately adjacent a heat generating component 205, which is optionally inside the heatsink shroud 234). The direct flow supply manifold 918 may distribute the received first portion of colder dielectric cooling fluid to the first area within the immersion coolant tank 1110 via the directed supply port(s) 706, which may include or be followed by the flow control device 718.

The tank bulk supply manifold 914 may be configured to receive a second portion of colder dielectric cooling fluid received from the tank bulk flow supply line 934 and distribute the second portion of the colder dielectric cooling fluid to a second area within the immersion coolant tank that is remote from the first area (e.g., a more generally region inside the tank, such as the bottom). The tank bulk supply manifold 914 may distribute the received second portion of colder dielectric cooling fluid to the second area within the immersion coolant tank directly, via multiple distribution ports, and/or via one or more distribution channels, conduits, or the like.

While the embodiments illustrated in the figures show the various pump(s), valves, and heat exchanger elements external to the tank, alternative embodiments in which some or all elements may be located within the tank are contemplated to be within the scope of the disclosure.

Example 1. An immersion cooling system including an immersion coolant tank configured to contain heat generating electronic equipment; a heat exchanger configured to remove heat absorbed by a first portion of a volume of dielectric cooling fluid within the immersion coolant tank; and an eductor configured to: receive the first portion of the volume of dielectric cooling fluid through a first port from the heat exchanger as motive fluid; receive a second portion of the volume of dielectric cooling fluid from the immersion coolant tank through a second port as a suction fluid, wherein the motive fluid creates suction by passing through the eductor, which suction draws the suction fluid into the eductor; mix the motive fluid with the suction fluid inside the eductor; and releasing the mixture of the motive fluid and the suction fluid through a third port.

Example 2. The immersion cooling system of example 1, wherein the eductor is configured to direct the mixture of the motive fluid and the suction fluid released through the third port toward at least a portion of the heat generating electronic equipment.

Example 3. The immersion cooling system of example 1, wherein the eductor is a liquid venturi eductor.

Example 4. The immersion cooling system of example 1, wherein the second portion of the volume of dielectric cooling fluid is drawn from an area within the immersion coolant tank that is immediately adjacent at least one heat generating component of the heat generating electronic equipment.

Example 5. The immersion cooling system of example 1, wherein the second portion of the volume of dielectric cooling fluid is drawn from an area within the immersion coolant tank that is remote from a mixing chamber of the eductor in which the motive fluid is mixed with the suction fluid.

Example 6. The immersion cooling system of example 1, further comprising a heatsink shroud at least partially enclosing at least one heat generating component of the heat generating electronic equipment, wherein the second portion of the volume of dielectric cooling fluid is drawn from within the heatsink shroud.

Example 7. The immersion cooling system of example 1, wherein the eductor is primarily disposed within the immersion coolant tank.

Example 8. The immersion cooling system of example 1, further comprising a heat removal system coupled to the heat exchanger and configured to cool a secondary coolant used by the heat exchanger to cool the first portion of the volume of dielectric cooling fluid.

Example 9. The immersion cooling system of example 1, further comprising a second heat exchanger configured to remove heat absorbed by the second portion of the volume of dielectric cooling fluid from the immersion coolant tank before being received in the eductor as the suction fluid.

Example 10. The immersion cooling system of example 9, wherein the second heat exchanger is a chiller.

Example 11. The immersion cooling system of example 9, further comprising a condensing unit coupled to the second heat exchanger.

Example 12. The immersion cooling system of example 1, wherein the heat exchanger configured to remove heat absorbed by the first portion of the volume of dielectric cooling fluid within the immersion coolant tank is a chiller.

Example 13. The immersion cooling system of example 12, further comprising a condensing unit coupled to the heat exchanger configured to remove heat absorbed by the first portion of the volume of dielectric cooling fluid.

Example 14. The immersion cooling system of example 1, wherein the heat exchanger is located outside the immersion coolant tank.

Example 15. An immersion cooling system for heat generating electronic equipment, comprising: an immersion coolant tank defining an open interior volume configured to hold the heat generating electronic equipment at least partially submerged in dielectric cooling fluid; a heat exchanger configured to receive a first portion of the dielectric cooling fluid released from the immersion coolant tank, wherein the heat exchanger is configured to cool and return the first portion of the dielectric cooling fluid to the immersion coolant tank; coolant circulation lines, wherein the coolant circulation lines include: a coolant return line fluidly coupling an outlet port of the immersion coolant tank to the heat exchanger; a coolant supply line fluidly coupling the heat exchanger to an inlet port of the immersion coolant tank; a coolant bypass line coupling the coolant return line to the coolant supply line, wherein the coolant bypass line is configured to enable a second portion of the dielectric cooling fluid released from the immersion coolant tank to bypass the heat exchanger before being delivered to the inlet port; a first pump configured to move the dielectric cooling fluid between the outlet port and the inlet port via the coolant circulation lines; and at least one bypass flow control device configured to control coolant flow to bypass the heat exchanger.

Example 16. The immersion cooling system of example 15, wherein the at least one bypass flow control device includes a valve disposed downstream of the first pump in at least one of the coolant circulation lines.

Example 17. The immersion cooling system of example 15, wherein the at least one bypass flow control device includes a second pump configured to move the dielectric cooling fluid between the heat exchanger and the inlet port.

Example 18. The immersion cooling system of example 15, wherein the outlet port provides a dielectric cooling fluid exit from a return manifold configured to release warmer dielectric cooling fluid from the immersion coolant tank.

Example 19. The immersion cooling system of example 15, wherein the inlet port provides a dielectric cooling fluid entrance to a supply manifold configured to receive and distribute colder dielectric cooling fluid into the immersion coolant tank.

Example 20. The immersion cooling system of example 19, further comprising: a directed coolant supply line configured to deliver at least a portion of the colder dielectric cooling fluid from the supply manifold to an area within the immersion coolant tank that is immediately adjacent to at least one heat generating component of the heat generating electronic equipment.

Example 21. The immersion cooling system of example 20, further comprising: a flow control device configured to control the flow of the portion of the colder dielectric cooling fluid from the supply manifold to the area within the immersion coolant tank immediately adjacent to the at least one heat generating component.

Example 22. The immersion cooling system of example 20, further comprising: a heatsink shroud at least partially enclosing the at least one heat generating component of the heat generating electronic equipment, wherein the portion of the colder dielectric cooling fluid delivered immediately adjacent to the at least one heat generating component is delivered within the heatsink shroud.

Example 23. The immersion cooling system of example 15, wherein the inlet port further comprises: a direct flow supply manifold configured to receive a first portion of a colder dielectric cooling fluid received from the coolant supply line and distribute the first portion of the colder dielectric cooling fluid to a first area within the immersion coolant tank that is immediately adjacent to at least one heat generating component of the heat generating electronic equipment; and a tank bulk supply manifold configured to receive a second portion of colder dielectric cooling fluid received from the coolant supply line and distribute the second portion of the colder dielectric cooling fluid to a second area within the immersion coolant tank that is remote from the first area.

Example 24. The immersion cooling system of example 23, wherein the coolant supply line includes a diverting valve for directing the first portion of the colder dielectric cooling fluid to the direct flow supply manifold and for directing the second portion of the colder dielectric cooling fluid to the tank bulk supply manifold.

Example 25. The immersion cooling system of example 24, wherein the diverting valve is an adjustable valve.

Example 26. The immersion cooling system of example 23, wherein the coolant supply line includes a second pump configured to control a flow ratio of the first portion of the colder dielectric cooling fluid that flows to the direct flow supply manifold and the second portion of the colder dielectric cooling fluid that flows to the tank bulk supply manifold.

Example 27. The immersion cooling system of example 26, wherein the coolant supply line branches into a direct flow supply line and tank bulk flow supply line, wherein the direct flow supply line is configured to deliver the first portion of the colder dielectric cooling fluid to the direct flow supply manifold and the tank bulk flow supply line is configured to deliver the second portion of the colder dielectric cooling fluid to the tank bulk supply manifold, wherein the second pump is disposed along the direct flow supply line.

Example 28. The immersion cooling system of example 27, wherein the coolant supply line includes a bypass branch line connecting the direct flow supply line and the tank bulk flow supply line, wherein the second pump is bypassed by the bypass branch line.

Example 29. The immersion cooling system of example 28, wherein the bypass branch line includes a valve for controlling a flow between the direct flow supply line and the tank bulk flow supply line.

Example 30. The immersion cooling system of example 28, wherein the bypass branch line includes a one-way check valve preventing a flow from the direct flow supply line to the tank bulk flow supply line.

The foregoing descriptions of systems, devices, and methods are provided merely as illustrative examples and are not intended to require or imply that the steps of the various embodiments must be performed in the order presented. As will be appreciated by one of skill in the art the order of steps in the foregoing embodiments may be performed in any order. Words such as “thereafter,” “then,” “next,” etc. are not intended to limit the order of the steps; these words are used to guide the reader through the description of the methods. Further, any reference to claim elements in the singular, for example, using the articles “a,” “an” or “the” is not to be construed as limiting the element to the singular.

The preceding description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the following claims and the principles and novel features disclosed herein.

What is claimed is:

1. An immersion cooling system, comprising:
an immersion coolant tank configured to contain heat generating electronic equipment;
a heat exchanger configured to remove heat absorbed by a first portion of a volume of dielectric cooling fluid within the immersion coolant tank; and
an eductor configured to:
receive the first portion of the volume of dielectric cooling fluid through a first port from the heat exchanger as motive fluid;
receive a second portion of the volume of dielectric cooling fluid from the immersion coolant tank through a second port as a suction fluid, wherein the motive fluid creates suction by passing through the eductor, which suction draws the suction fluid into the eductor;
mix the motive fluid with the suction fluid inside the eductor; and
releasing the mixture of the motive fluid and the suction fluid through a third port.

2. The immersion cooling system of claim 1, wherein the eductor is configured to direct the mixture of the motive fluid and the suction fluid released through the third port toward at least a portion of the heat generating electronic equipment.

3. The immersion cooling system of claim 1, wherein the eductor is a liquid venturi eductor.

4. The immersion cooling system of claim 1, wherein the second portion of the volume of dielectric cooling fluid is drawn from an area within the immersion coolant tank that is immediately adjacent at least one heat generating component of the heat generating electronic equipment.

5. The immersion cooling system of claim 1, wherein the second portion of the volume of dielectric cooling fluid is drawn from an area within the immersion coolant tank that is remote from a mixing chamber of the eductor in which the motive fluid is mixed with the suction fluid.

6. The immersion cooling system of claim 1, further comprising:
a heatsink shroud at least partially enclosing at least one heat generating component of the heat generating electronic equipment, wherein the second portion of the volume of dielectric cooling fluid is drawn from within the heatsink shroud.

7. The immersion cooling system of claim 1, wherein the eductor is primarily disposed within the immersion coolant tank.

8. The immersion cooling system of claim 1, further comprising a heat removal system coupled to the heat exchanger and configured to cool a secondary coolant used by the heat exchanger to cool the first portion of the volume of dielectric cooling fluid.

9. The immersion cooling system of claim 1, further comprising:
a second heat exchanger configured to remove heat absorbed by the second portion of the volume of dielectric cooling fluid from the immersion coolant tank before being received in the eductor as the suction fluid.

10. The immersion cooling system of claim 9, wherein the second heat exchanger is a chiller.

11. The immersion cooling system of claim 9, further comprising a condensing unit coupled to the second heat exchanger.

12. The immersion cooling system of claim 1, wherein the heat exchanger configured to remove heat absorbed by the first portion of the volume of dielectric cooling fluid within the immersion coolant tank is a chiller.

13. The immersion cooling system of claim 12, further comprising a condensing unit coupled to the heat exchanger configured to remove heat absorbed by the first portion of the volume of dielectric cooling fluid.

14. The immersion cooling system of claim 1, wherein the heat exchanger is located outside the immersion coolant tank.

15. An immersion cooling system for heat generating electronic equipment, comprising:
an immersion coolant tank defining an open interior volume configured to hold the heat generating electronic equipment at least partially submerged in dielectric cooling fluid;
a heat exchanger configured to receive a first portion of the dielectric cooling fluid released from the immersion coolant tank, wherein the heat exchanger is configured to cool and return the first portion of the dielectric cooling fluid to the immersion coolant tank;
coolant circulation lines, wherein the coolant circulation lines include:
a coolant return line fluidly coupling an outlet port of the immersion coolant tank to the heat exchanger;
a coolant supply line fluidly coupling the heat exchanger to an inlet port of the immersion coolant tank;
a coolant bypass line coupling the coolant return line to the coolant supply line, wherein the coolant bypass line is configured to enable a second portion of the dielectric cooling fluid released from the immersion coolant tank to bypass the heat exchanger before being delivered to the inlet port;
a first pump configured to move the dielectric cooling fluid between the outlet port and the inlet port via the coolant circulation lines; and
at least one bypass flow control device configured to control coolant flow to bypass the heat exchanger.

16. The immersion cooling system of claim 15, wherein the at least one bypass flow control device includes a valve disposed downstream of the first pump in at least one of the coolant circulation lines.

17. The immersion cooling system of claim 15, wherein the at least one bypass flow control device includes a second pump configured to move the dielectric cooling fluid between the heat exchanger and the inlet port.

18. The immersion cooling system of claim 15, wherein the outlet port provides a dielectric cooling fluid exit from a return manifold configured to release warmer dielectric cooling fluid from the immersion coolant tank.

19. The immersion cooling system of claim 15, wherein the inlet port provides a dielectric cooling fluid entrance to a supply manifold configured to receive and distribute colder dielectric cooling fluid into the immersion coolant tank.

20. The immersion cooling system of claim 19, further comprising:
a directed coolant supply line configured to deliver at least a portion of the colder dielectric cooling fluid from the supply manifold to an area within the immersion coolant tank that is immediately adjacent to at least one heat generating component of the heat generating electronic equipment.

21. The immersion cooling system of claim 20, further comprising:
a flow control device configured to control the flow of the portion of the colder dielectric cooling fluid from the supply manifold to the area within the immersion coolant tank immediately adjacent to the at least one heat generating component.

22. The immersion cooling system of claim 20, further comprising:
a heatsink shroud at least partially enclosing the at least one heat generating component of the heat generating electronic equipment, wherein the portion of the colder dielectric cooling fluid delivered immediately adjacent to the at least one heat generating component is delivered within the heatsink shroud.

23. The immersion cooling system of claim 15, wherein the inlet port further comprises:
a direct flow supply manifold configured to receive a first portion of a colder dielectric cooling fluid received from the coolant supply line and distribute the first portion of the colder dielectric cooling fluid to a first area within the immersion coolant tank that is immediately adjacent to at least one heat generating component of the heat generating electronic equipment; and
a tank bulk supply manifold configured to receive a second portion of colder dielectric cooling fluid received from the coolant supply line and distribute the second portion of the colder dielectric cooling fluid to a second area within the immersion coolant tank that is remote from the first area.

24. The immersion cooling system of claim 23, wherein the coolant supply line includes a diverting valve for directing the first portion of the colder dielectric cooling fluid to the direct flow supply manifold and for directing the second portion of the colder dielectric cooling fluid to the tank bulk supply manifold.

25. The immersion cooling system of claim 24, wherein the diverting valve is an adjustable valve.

26. The immersion cooling system of claim 23, wherein the coolant supply line includes a second pump configured to control a flow ratio of the first portion of the colder dielectric cooling fluid that flows to the direct flow supply manifold and the second portion of the colder dielectric cooling fluid that flows to the tank bulk supply manifold.

27. The immersion cooling system of claim 26, wherein the coolant supply line branches into a direct flow supply line and tank bulk flow supply line, wherein the direct flow supply line is configured to deliver the first portion of the colder dielectric cooling fluid to the direct flow supply manifold and the tank bulk flow supply line is configured to deliver the second portion of the colder dielectric cooling fluid to the tank bulk supply manifold, wherein the second pump is disposed along the direct flow supply line.

28. The immersion cooling system of claim 27, wherein the coolant supply line includes a bypass branch line connecting the direct flow supply line and the tank bulk flow supply line, wherein the second pump is bypassed by the bypass branch line.

29. The immersion cooling system of claim 28, wherein the bypass branch line includes a valve for controlling a flow between the direct flow supply line and the tank bulk flow supply line.

30. The immersion cooling system of claim 28, wherein the bypass branch line includes a one-way check valve preventing a flow from the direct flow supply line to the tank bulk flow supply line.
